(19) United States
(12) Patent Application Publication
(10) Pub. No.: US 2011/0034015 A1
(43) Pub. Date: Feb. 10, 2011

(54) HEAT TREATMENT APPARATUS AND METHOD FOR MANUFACTURING SEMICONDUCTOR DEVICE

(75) Inventors: Kenichi Yoshino, Oita-ken (JP); Takayuki Ito, Oita-ken (JP); Kunihiro Miyazaki, Oita-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/796,147

(22) Filed: Jun. 8, 2010

(30) Foreign Application Priority Data
Aug. 10, 2009 (JP) 2009-186042

(51) Int. Cl. H01L 21/28; H01L 21/26; F27B 5/06

(52) U.S. Cl. 438/585; 438/795; 392/418; 257/E21.328; 257/E21.19

(57) ABSTRACT

According to one embodiment, a heat treatment apparatus includes a light emitting unit to emit light to irradiate a wafer, a processing unit with a stage section and a control unit. The control unit implements a first irradiation to irradiate the light onto the wafer. After the first irradiation, the control unit changes at least one selected from a disposition of the wafer, a distribution of an intensity of the light on a major surface of the stage section along a circumferential edge direction of the wafer, and a distribution of a temperature of the wafer in a supplemental heating by the stage section along a circumferential edge direction of the wafer. After the changing, the control unit implements a second irradiation to irradiate the light onto the wafer. Durations of the first irradiation and the second irradiation are shorter than a time necessary for the changing.

### CROSS-REFERENCE TO RELATED APPLICATIONS

This application is based upon and claims the benefit of priority from the prior Japanese Patent Application No. 2009-186042, filed on Aug. 10, 2009; the entire contents of which are incorporated herein by reference.

### FIELD

Embodiments described herein relate generally to a heat treatment apparatus and a method for manufacturing a semiconductor device.

### BACKGROUND

As the elements of semiconductor devices are downscaled, parasitic resistance and short channel effects increase for MOSFETs of semiconductor devices. Therefore, it is important to form shallow active layers having low resistance.

Although it is necessary to perform high temperature activation heat treatment of the impurities to reduce the resistance of the active layer, RTA (Rapid Thermal Anneal) processing using a conventional halogen lamp diffuses the impurities during the activation heat treatment; and the diffusion region undesirably enlarges. Therefore, it has been difficult to achieve both a reduction of the resistance of the active layer and a formation of a shallow active layer.

Conversely, annealing methods have been discussed to instantaneously supply thermal energy using, for example, a flash lamp or laser (for example, refer to JP-A 2007-123844 (Kokai)). However, heat does not sufficiently diffuse in the wafer surface by such an ultra rapid thermal annealing method. Therefore, fluctuation of the temperature in the wafer surface increases.

Although it is possible to reduce the temperature fluctuation in the surface by rotating the wafer during the heat treatment during conventional RTA processing and thermal diffusion furnace processing, such ultra rapid thermal annealing completes the heat treatment in an ultra short period of time, e.g., 1 to 10 ms. Therefore, an unrealistic rate of 100,000 rpm or more would be necessary to improve the temperature distribution in the surface by rotating the wafer.

### BRIEF DESCRIPTION OF THE DRAWINGS

FIG. 1 is a schematic view illustrating the configuration of the heat treatment apparatus according to the first embodiment;

FIG. 2 is a flowchart illustrating operations of the heat treatment apparatus;

FIGS. 3A to 3E are schematic views illustrating operations of the heat treatment apparatus;

FIGS. 4A to 4C are schematic views illustrating evaluation results of characteristics of the heat treatment apparatus;

FIGS. 5A to 5C are graphs illustrating evaluation results of characteristics of the heat treatment apparatus;

FIG. 6 is a graph illustrating a characteristic of the light of the heat treatment apparatus;

FIGS. 7A to 7F are graphs illustrating operations of the heat treatment apparatus according to the first embodiment and a heat treatment apparatus of a comparative example;

FIGS. 8A to 8E are schematic cross-sectional views in order of the processes, illustrating the method for manufacturing the semiconductor device using the heat treatment apparatus;

FIGS. 9A to 9G are schematic cross-sectional views in order of the processes, illustrating another method for manufacturing the semiconductor device using the heat treatment apparatus;

FIG. 10 is a schematic view illustrating the configuration of another heat treatment apparatus according to the first embodiment;

FIGS. 11A to 11D are schematic views illustrating operations of other heat treatment apparatuses according to the first embodiment;

FIG. 12 is a flowchart illustrating another operation of the heat treatment apparatus according to the first embodiment;

FIG. 13 is a flowchart illustrating another operation of the heat treatment apparatus according to the first embodiment;

FIGS. 14A to 14C are schematic views illustrating the configuration and operations of a heat treatment apparatus according to a second embodiment;

FIGS. 15A and 15B are schematic views illustrating filters usable in the heat treatment apparatus according to the second embodiment;

FIGS. 16A to 16C are schematic views illustrating the configuration and operations of another heat treatment apparatus according to the second embodiment;

FIGS. 17A to 17C are schematic views illustrating the configuration and operations of another heat treatment apparatus according to the second embodiment;

FIGS. 18A to 18C are schematic views illustrating the configuration and operations of a heat treatment apparatus according to a third embodiment;

FIG. 19 is a schematic view illustrating a susceptor used in the heat treatment apparatus;

FIGS. 20A to 20C are schematic cross-sectional views illustrating other susceptors used in the heat treatment apparatus;

FIGS. 21A and 21B are schematic views illustrating the configuration and operations of a heat treatment apparatus according to a fourth embodiment; and

FIG. 22 is a flowchart illustrating a method for manufacturing a semiconductor apparatus according to a fifth embodiment.

### DETAILED DESCRIPTION

In general, according to one embodiment, a heat treatment apparatus includes a light emitting unit, a processing unit and a control unit. The light emitting unit emits light to irradiate a wafer. The processing unit includes a stage section. The wafer is placed on the stage section. The control unit implements a first irradiation to irradiate the light onto the wafer placed on the stage section. After the first irradiation, the control unit changes at least one selected from a disposition of the wafer, a distribution of an intensity of the light on a major surface of the stage section along a circumferential edge direction of the wafer, and a distribution of a temperature of the wafer in a supplemental heating by the stage section along a circumferential edge direction of the wafer. After the changing, the control unit implements a second irradiation to irradiate the light onto the wafer. A duration of the first irradiation and a duration of the second irradiation are shorter than a time necessary for the changing.

In another embodiment, a method for manufacturing a semiconductor device is disclosed. The method includes implementing a first irradiation to irradiate light onto a wafer. Then method further includes changing, after the first irradiation, at least one selected from a disposition of the wafer, a distribution of an intensity of the light on a major surface of the wafer along a circumferential edge direction of the wafer, and a distribution of a supplemental heating temperature of the wafer along the circumferential edge direction of the wafer. The method includes implementing, after the changing, a second irradiation to irradiate the light onto the wafer. A duration of the first irradiation and a duration of the second irradiation are shorter than a time necessary for the changing.

Exemplary embodiments of the invention will now be described with reference to the drawings.

The drawings are schematic or conceptual; and the relationships between the thickness and width of portions, the proportional coefficients of sizes among portions, etc., are not necessarily the same as the actual values thereof. Further, the dimensions and proportional coefficients may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

A heat treatment apparatus according to a first embodiment of the invention is a heat treatment apparatus which can be utilized, for example, to perform heat treatment to activate an impurity implanted into a wafer made of a semiconductor such as silicon, etc.

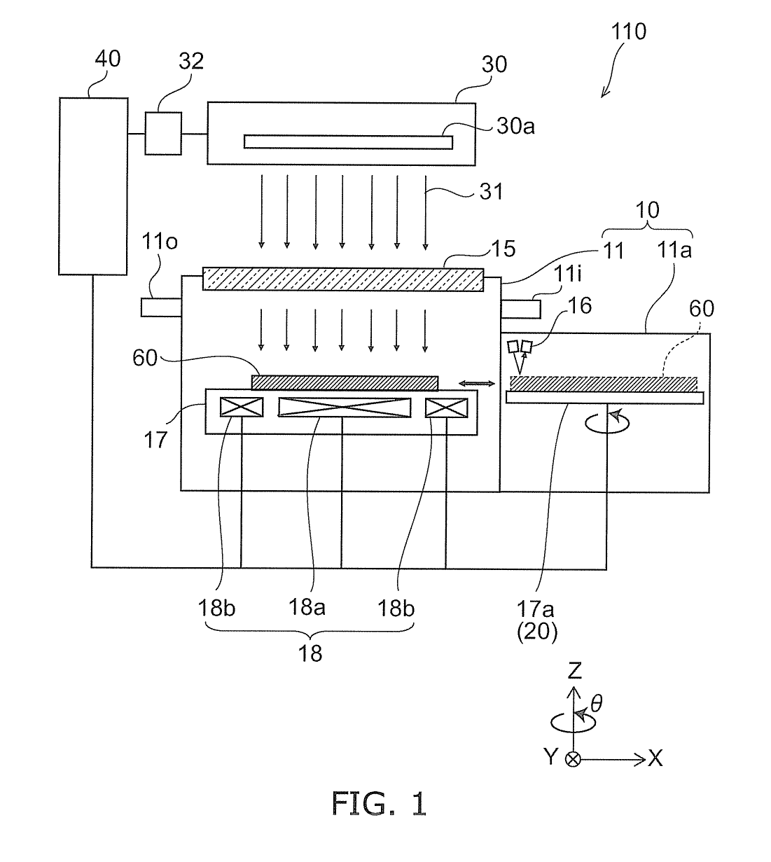

FIG. 1 is a schematic view illustrating the configuration of the heat treatment apparatus according to the first embodiment.

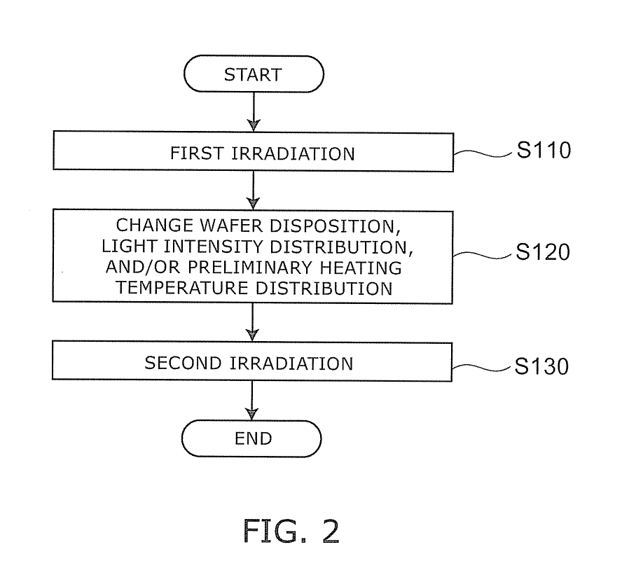

FIG. 2 is a flowchart illustrating operations of the heat treatment apparatus according to the first embodiment. As illustrated in FIG. 1, a heat treatment apparatus 110 according to this embodiment includes a light emitting unit 30, a processing unit 10, and a control unit 40.

The light emitting unit 30 emits light 31 to irradiate a wafer 60 on which heat treatment is performed in the heat treatment apparatus 110. The light 31 is a light pulse having, for example, a pulse width of not less than 0.1 ms (milliseconds) and not more than 100 ms.

The light emitting unit 30 may include a lamp 30a such as, for example, a xenon flash lamp. Also, the light emitting unit 30 may include various lamps using, for example, other noble gases, mercury, and hydrogen and, for example, xenon arc discharge lamps and the like. The light emitting unit 30 may include such lamps 30a multiply arranged. For example, the lamp 30a used in the light emitting unit 30 may include rod-shaped lamps to realize a high luminance.

The light emitting unit 30 also may include a pulse laser emitting various light pulses. In such a case, laser light (the light 31) emitted by, for example, a laser is scanned over the major surface of the wafer 60 such that each surface portion of the wafer 60 irradiated with the laser pulse is irradiated substantially as if with the light 31 having a pulse width not less than 0.1 ms and not more than 100 ms.

Such a laser may include various lasers such as an excimer laser, YAG laser, carbon monoxide gas laser, and carbon dioxide laser.

The case will now be described where the light emitting unit 30 includes the lamp 30a including multiple xenon flash lamps having rod configurations.

A power source 32 may be provided in the light emitting unit 30 to supply power to such a lamp 30a to emit light. The power source 32 may be included in the control unit 40.

The processing unit 10 includes a stage 17 (the stage section) on which the wafer 60, on which heat treatment is performed in the heat treatment apparatus 110, is placed.

In this specific example, the processing unit 10 includes a processing chamber 11 and an antechamber 11a.

The stage 17 is provided in the interior of the processing chamber 11. A window unit 15 permeable to the light 31 is provided in the processing chamber 11. A gas inlet 11i and a gas outlet 11o also are provided in the processing chamber 11 as necessary. The window unit 15 transmits the light 31 to irradiate the light 31 onto the wafer 60 and simultaneously isolates the processing chamber 11 from the light emitting unit 30 to provide an airtight interior of the processing chamber 11.

The antechamber 11a is, for example, a receiving unit of the wafer 60. In the antechamber 11a, for example, a cassette storing the wafer 60 is received; the wafer 60 is placed on an antechamber stage 17a; the position, for example, of the wafer 60 is adjusted; and the wafer 60 is subsequently transferred from the antechamber 11a into the processing chamber 11. The processing unit 10 may further include a loading unit to dispatch the wafer 60 after the processing of the processing chamber 11 is completed.

The wall face of the processing chamber 11 may include, for example, metal such as stainless steel. The stage 17 may include aluminum nitride (AIN), silicon carbide (SIC), quartz, etc. The window unit 15 may include, for example, synthetic quartz and the like.

A heater 18 is provided in the interior of the stage 17 to provide supplemental heating of the wafer 60. In this specific example, the heater 18 includes an inner heater 18a provided on the central side of the major surface of the stage 17 and an outer heater 18b provided on the peripheral side. The inner heater 18a has, for example, a discal configuration. The outer heater 18b has a circular ring configuration centered on the center of the inner heater 18a. However, the configurations thereof are arbitrary.

The heater 18 (e.g., the inner heater 18a and the outer heater 18b) may include, for example, a metal heater having a resistance heating wire buried therein, an infrared heating lamp such as a halogen lamp, etc. The temperature of the heater 18 (e.g., the inner heater 18a and the outer heater 18b) may be controlled, for example, by the control unit 40. In such a case, the temperature of the heater 18 provided in the stage 17 may be detected by, for example, a thermocouple thermometer buried in the interior of the stage and controlled by, for example, the control unit 40 based on the detection result.

For example, the wafer 60 transferred via the antechamber 11a is placed on the stage 17 of the processing chamber 11. The heat treatment of the wafer 60 is performed by the light 31 emitted by the light emitting unit 30 being irradiated on the wafer 60 via the window unit 15.

In such a case, the control unit 40 performs the following operations.

Namely, as illustrated in FIG. 2, first, a first irradiation is implemented to irradiate the light 31 onto the wafer 60 placed on the stage 17 (step S110).

Then, after the first irradiation, at least one selected from the disposition of the wafer 60, the distribution of the intensity of the light 31 on the major surface of the stage 17 along the circumferential edge direction of the wafer, and the distribution of the temperature of the wafer 60 in the supplemental heating by the stage 17 along the circumferential edge direction of the wafer is changed (step S120).

Continuing, after the changing, a second irradiation is implemented to irradiate the light 31 onto the wafer 60 (step S130).

At this time, the durations of the irradiation of the light 31 of the first irradiation and the second irradiation are shorter than the time necessary for the changing recited above.

Thereby, an ultra rapid heat treatment can be implemented having reduced temperature fluctuation in the surface of the wafer 60; and a semiconductor device can be manufactured in which a shallow active layer having a low resistance is formed with good uniformity.

Here, an orientation angle of the wafer 60 may be used as the disposition of the wafer 60 recited above.

First, the case will be described where the orientation angle of the wafer 60 is changed from the first irradiation as step S120.

As described below, the orientation angle of the wafer 60 is an orientation angle having an axis in a direction perpendicular to the major surface of the wafer 60; and is a relative orientation angle of the wafer 60 in the processing unit 10.

Herein, as illustrated in FIG. 1, a direction perpendicular to the major surface of the stage 17 is taken as a Z axis direction. One direction perpendicular to the Z axis direction is taken as an X axis direction. A direction perpendicular to the Z axis direction and the X axis direction is taken as a Y axis direction. An angle of the rotation around the Z axis is taken as an orientation angle θ.

Herein, when the wafer 60 is placed on the stage 17, the directions perpendicular to the major surface of the wafer 60 are parallel to the Z axis direction. The relative orientation angle of the wafer 60 with respect to the processing unit 10 may be taken as, for example, an orientation angle of the wafer 60 with respect to any reference of the processing unit 10 (e.g., a reference based on, for example, a wall face, etc., of the processing unit 10).

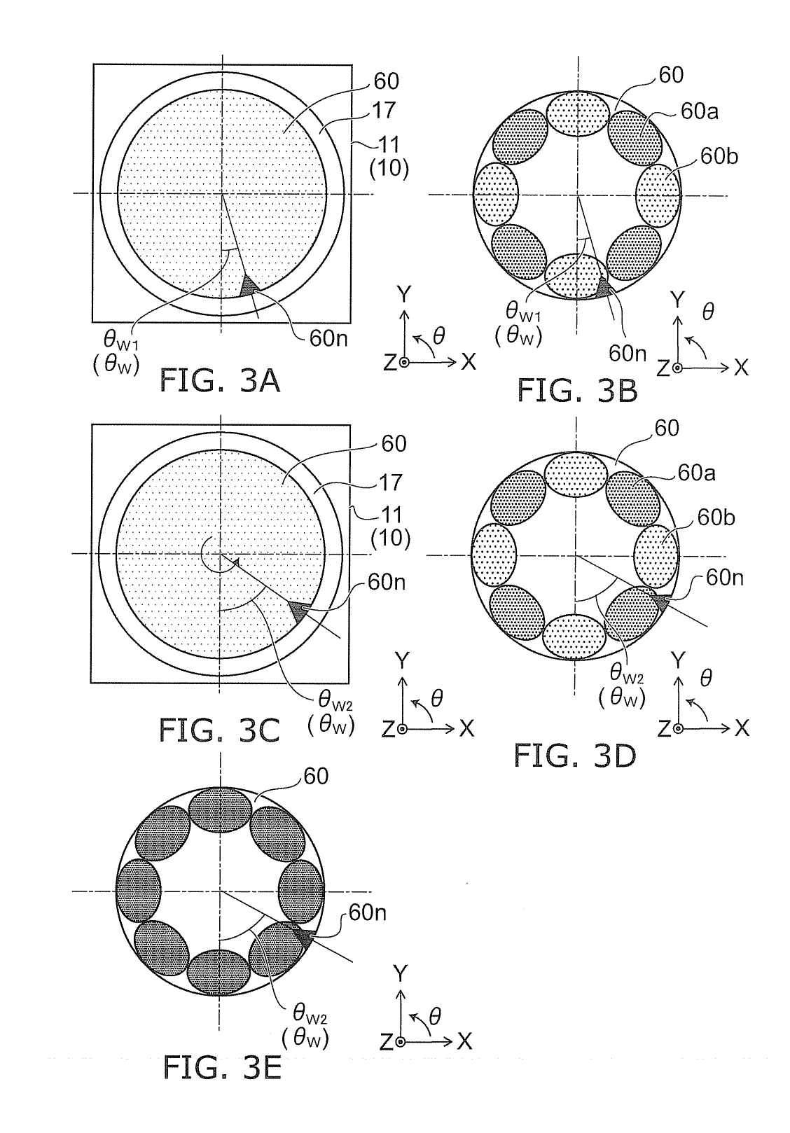

FIGS. 3A to 3E are schematic views illustrating operations of the heat treatment apparatus according to the first embodiment.

Namely, FIG. 3A illustrates the disposition of the wafer 60 when the first irradiation of step S110 is performed. FIG. 3B illustrates the surface temperature distribution of the wafer 60 of the first irradiation. FIG. 3C illustrates the disposition of the wafer 60 changed in step S120. FIG. 3D illustrates the surface temperature distribution of the wafer 60 of the second irradiation. FIG. 3E illustrates the distribution in the wafer 60 of the thermal history after the second irradiation.

As illustrated in FIG. 3A, the wafer 60 is disposed on the stage 17 with a first wafer orientation angle θ_{W1} during the first irradiation. In other words, during the first irradiation, the orientation angle (the wafer orientation angle θ_{W}) of the wafer 60 having the processing unit 10 as a reference is the first wafer orientation angle θ_{W1}. At this time, the wafer orientation angle θ_{W} may be determined, for example, by the angle between a prescribed reference and a notch portion 60n, an orientation flat, a prescribed marking, etc., of the wafer 60.

A temperature distribution such as that illustrated in FIG. 3B is formed by irradiating the light 31 onto the wafer 60 in this state. In other words, in FIG. 3B, the dark hatching illustrates a high temperature region 60a having a relatively high temperature; and the light hatching illustrates a low temperature region 60b having a relatively low temperature. In this specific example, the high temperature region 60a and the low temperature region 60b are formed each with a wafer orientation angle θ_{W} period of 90 degrees.

Such a distribution of the temperature in the major surface of the wafer 60 is caused by fluctuations such as the distribution in the surface of the light emission intensity of the light emitting unit 30, the light reflection characteristics of the wall faces, etc., of the processing chamber 11, the optical characteristics of the window unit 15, the distribution in the surface of the temperature of the stage 17, and the thermal conduction characteristics from the stage 17 to the wafer 60. Such various components combine to form the distribution in of the temperature in the major surface of the wafer 60. The distribution of the temperature in the major surface of the wafer 60 includes at least the distribution of the temperature differing along the circumference centered on the center of the major surface of the wafer 60.

The distribution in the surface of the temperature results from the characteristics of the light emitting unit 30 and the processing chamber 11 and is substantially constant for multiple irradiations of the light 31.

Then, as illustrated in FIG. 3C, after the first irradiation, the wafer orientation angle θ_{W} of the wafer 60 is changed from that of the first irradiation and set to a second wafer orientation angle θ_{W2} (step S120). For example, the difference between the second wafer orientation angle θ_{W2} after the change and the first wafer orientation angle θ_{W1} during the first irradiation may be, for example, an angle of 45 degrees. For example, the position of the notch portion 60n of the wafer 60 may be rotated 45 degrees from the state of the first irradiation.

Continuing, in the state of being disposed at the second wafer orientation angle θ_{W2}, the light 31 is irradiated onto the wafer 60 (step S130). Thereby, a temperature distribution such as that illustrated in FIG. 3D is formed. In other words, the disposition of the high temperature region 60a and the low temperature region 60b is the same disposition as that of the first irradiation when the processing unit 10 is taken as the reference. When the wafer 60 is taken as the reference, the high temperature region 60a and the low temperature region 60b have a disposition different from that of the first irradiation. In other words, when the wafer 60 is taken as the reference, the high temperature region 60a and the low temperature region 60b are rotated 45 degrees from the disposition during the first irradiation.

Therefore, the high temperature region 60a and the low temperature region 60b are in an averaged state for the wafer 60 after the first irradiation and the second irradiation as illustrated in FIG. 3E; and the thermal history can be made uniform over the surface of the wafer 60.

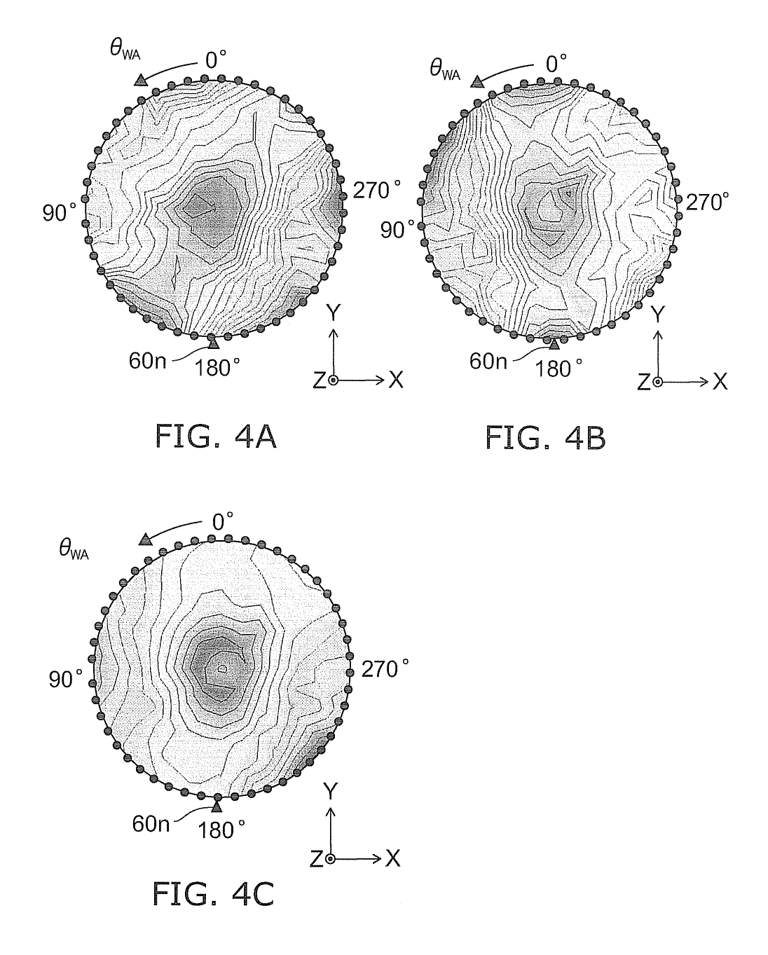

FIGS. 4A to 4C are schematic views illustrating evaluation results of characteristics of the heat treatment apparatus according to the first embodiment. Namely, FIG. 4A is a schematic view illustrating the surface temperature distribution of the wafer 60 during the first irradiation at the first wafer orientation angle θ_{W1} which corresponds to the state of the wafer 60 after step S110. FIG. 4B illustrates the surface temperature distribution of the wafer 60 when the light 31 is irradiated at the second wafer orientation angle θ_{W2}. FIG. 4C is a schematic view illustrating the distribution in the surface of the effective temperature of the wafer 60 when the second irradiation is implemented at the second wafer orientation angle θ_{W2} after the first irradiation at the first wafer orientation angle θ_{W1} corresponding to the state of the wafer 60 after step S130.

These drawings illustrate the calculated temperature corresponding to the temperature of the wafer 60 during irradiation with the light 31 ascertained from the distribution in the surface of the sheet resistance measured for each portion of the major surface of the wafer 60 for each processing. In other words, the calculated temperature of the heat treatment during the irradiation with the light 31 can be estimated from the sheet resistance of the wafer 60 based on the tendency for the sheet resistance to decrease as the heat treatment temperature of the wafer 60 increases. In the case of the multiple light irradiations illustrated in FIG. 4C, the calculated temperature is ascertained as one light irradiation.

In these drawings, the dark hatching illustrates relatively high temperatures; and the light hatching illustrates relatively low temperatures.

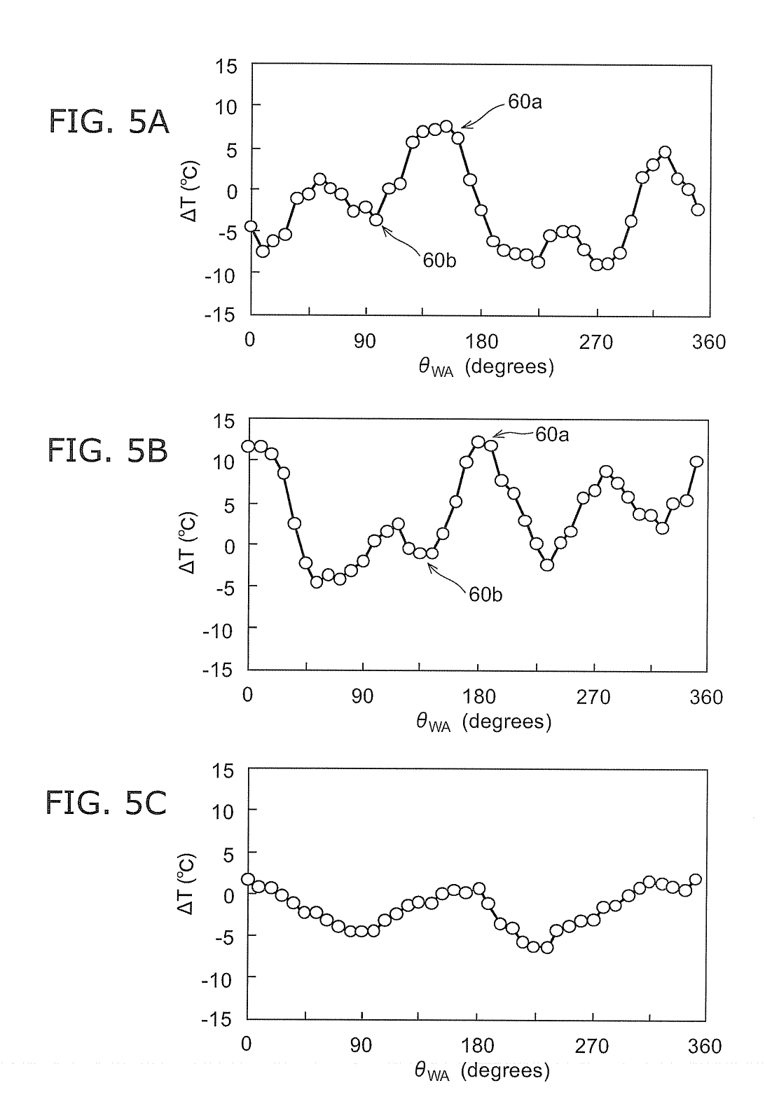

FIGS. 5A to 5C are graphs illustrating evaluation results of characteristics of the heat treatment apparatus according to the first embodiment.

Namely, FIG. 5A is a graph illustrating the distribution in the surface of the calculated temperature of the wafer 60 due to the first irradiation at the first wafer orientation angle θ_{W1}. FIG. 5B illustrates the distribution in the surface of the calculated temperature of the wafer 60 when irradiated with the light 31 at the second wafer orientation angle θ_{W2}. FIG. 5C is a schematic view illustrating the distribution in the surface of the calculated temperature of the wafer 60 when the second irradiation is implemented at the second wafer orientation angle θ_{W2} after the first irradiation is implemented at the first wafer orientation angle θ_{W1}. In other words, FIGS. 5A to 5C are graphs in which the calculated temperature of the peripheral portion of the wafer 60 is extracted from the measurement result of the distribution in the surface of the calculated temperature illustrated in FIGS. 4A to 4C, respectively. In FIGS. 5A to 5C, an angle θ_{WA} (degrees) in the surface of the wafer 60 is plotted on the horizontal axis; and a temperature difference ΔT (° C.), i.e., the difference between the calculated temperature and a prescribed reference temperature, is plotted on the vertical axis.

The characteristics illustrated in FIGS. 4A to 4C and FIGS. 5A to 5C are characteristics having the wafer 60 as a reference and are illustrated with the notch portion 60n of the wafer 60 disposed at a position such that the angle θ_{WA} is 180 degrees) (°).

In this example, the first wafer orientation angle θ_{W1} is 5 degrees and the second wafer orientation angle θ_{W2} is 140 degrees. In other words, in this example, the difference between the second wafer orientation angle θ_{W2} and the first wafer orientation angle θ_{W1} is 135 degrees; and the second wafer orientation angle θ_{W2} is changed from the first wafer orientation angle θ_{W1} by an angle that is a multiple of 45 degrees.

As illustrated in FIG. 4A and FIG. 5A, the fluctuation of the temperature (the calculated temperature) in the surface of the wafer 60 in the first irradiation in which the wafer 60 is irradiated with the light 31 at the first wafer orientation angle θ_{W1} is large, that is, −8° C. to +7° C. As illustrated in FIG. 5A, the difference between the angle θ_{WA} of the high temperature region 60a and the angle θ_{WA} of the low temperature region 60b is about 45 degrees; and this characteristic repeats

As illustrated in FIG. 4B and FIG. 5B, the fluctuation of the temperature (the calculated temperature) in the surface of the wafer 60 when the wafer 60 is irradiated with the light 31 at the second wafer orientation angle θ_{W2} also is large, that is, −5° C. to +12° C. As illustrated in FIG. 5B, the difference between the angle θ_{WA} of the high temperature region 60a and the angle θ_{WA} of the low temperature region 60b is about 45 degrees; and this characteristic repeats. The angle θ_{WA} of the high temperature region 60a in FIG. 5B is shifted 45 degrees from the angle θ_{WA} of the high temperature region 60a in FIG. 5A. Similarly, the angle θ_{WA} of the low temperature region 60b in FIG. 5B is shifted 45 degrees from the angle θ_{WA} of the low temperature region 60b in FIG. 5A. The shift of these angles θ_{WA} results from the difference between the second wafer orientation angle θ_{W2} and the first wafer orientation angle θ_{W1} being 135 degrees.

As illustrated in FIG. 4C and FIG. 5C, the fluctuation of the temperature (the calculated temperature) in the surface of the wafer 60 when the second irradiation is performed at the second wafer orientation angle θ_{W2} after the first irradiation is performed at the first wafer orientation angle θ_{W1} is −6° C. to +3° C. In other words, in the case where the wafer orientation angle θ_{W} of the wafer 60 is changed and light irradiation is performed twice, the fluctuation of the temperature in the surface can be smaller than that of the case of FIG. 4A and FIG. 5A and the case of FIG. 4B and FIG. 5B having one irradiation each.

Thus, according to the heat treatment apparatus 110 according to this embodiment, an ultra rapid heat treatment can be implemented with reduced temperature fluctuation in the surface of the wafer 60.

In other words, in the case where a rod-shaped lamp, for example, is used as the lamp 30a of the light emitting unit 30 and multiple heaters 18 (the inner heater 18a and the outer heater 18b) disposed in a concentric-circular configuration are used as the heater 18 of the stage 17 to reduce costs and realize a long life, the temperature control using power control of the lamp 30a and power control of the heater 18 can be performed easily in the diameter direction in the surface of the wafer 60 from the central portion toward the peripheral portion. Conversely, the temperature control is difficult in the circumferential direction centered on the center of the wafer 60. Further, the peripheral portion of the wafer 60 has a circumferential length longer than that of the inside; and heat easily escapes. Also, the temperature distribution tends to have a periodicity along the circumferential direction from the symmetry unique to the apparatus due to effects of the geometric structure of the heat treatment apparatus. Therefore, the fluctuation of the temperature tends to increase in the circumferential direction of the wafer 60 for one light irradiation.

Conversely, in the heat treatment apparatus 110 according to this embodiment and the method for manufacturing the semiconductor device according to an embodiment of the invention, by focusing on the periodicity of the temperature fluctuation in the circumferential direction (the circumferential edge direction of the wafer 60), an ultra rapid heat treatment can be realized in which the temperature fluctuation in the surface of the wafer 60 is reduced by changing the wafer orientation angle θ_{W} and performing multiple irradiations with the light 31.

The irradiation duration, i.e., the pulse width of the light 31, may be changed between the first irradiation and the second irradiation; the intensity of the light 31 may be changed between the first irradiation and the second irradiation; and the irradiation energy of the light 31 may be changed between the first irradiation and the second irradiation.

In step S120, the method for changing the wafer orientation angle θ_{W} of the wafer 60 is arbitrary.

For example, as illustrated in FIG. 1, the wafer orientation angle θ_{W} is set to the first wafer orientation angle θ_{W1} on the antechamber stage 17a; in this state, the wafer 60 is transferred into the processing chamber 11; the wafer 60 is placed onto the stage 17; and the first irradiation is performed at the first wafer orientation angle θ_{W1} (step S110). Subsequently, the wafer 60 is moved into the antechamber 11a; the wafer orientation angle θ_{W} is set to the second wafer orientation angle θ_{W2} on the antechamber stage 17a (step S120); in this state, the wafer 60 is transferred into the processing chamber 11; and the wafer 60 is placed onto the stage 17. Then, the second irradiation is performed at the second wafer orientation angle θ_{W2} (step S130). Thus, the processing to change the wafer orientation angle θ_{W} of the wafer 60 may be performed in the antechamber 11a.

In other words, in the heat treatment apparatus 110, the antechamber stage 17a is provided in the antechamber 11a which is a portion of the processing unit 10 as a wafer disposition control unit 20 and is capable of changing the wafer orientation angle θ_{W} of the wafer 60, i.e., the disposition of the wafer 60.

Operations of such an antechamber stage 17a (the wafer disposition control unit 20), i.e., operations to control the wafer orientation angle θ_{W}, may be performed, for example, by the control unit 40.

In other words, for example, a control program stored in the control unit 40 may include a program (an operation recipe) to cause the antechamber stage 17a to implement the operation of disposing the wafer orientation angle θ_{W} at the first wafer orientation angle θ_{W1} and the operation of disposing the wafer orientation angle θ_{W} at the second wafer orientation angle θ_{W2}.

The control program stored in the control unit 40 includes programs to sequentially implement step S110, step S120, step S130, and the accompanying processing (e.g., movement of the wafer 60 implemented as necessary, etc.).

In such a case, a detection unit 16 may be provided in the interior of the antechamber 11a to detect the wafer orientation angle θ_{W} of the wafer 60 placed on the antechamber stage 17a, i.e., the disposition of the wafer 60. In other words, the processing unit 10 may further include the detection unit 16 to detect the disposition of the wafer 60.

The control unit 40 changes the disposition (e.g., the wafer orientation angle θ_{W}) of the wafer 60 based on the detection result of the disposition (e.g., the wafer orientation angle θ_{W}) of the wafer 60 detected by the detection unit 16.

The detection unit 16 may include, for example, a light emitting unit and a light receiving unit and a configuration to optically detect the notch portion 60n, the orientation flat, etc., of the wafer 60. In such a case, the wafer orientation angle θ_{W} is detected by utilizing at least one selected from reflected light and transmitted light at a designated portion of the wafer 60. Also, a method may be employed to bring a pin into contact with the end portion of the wafer 60 to mechanically detect the position of a designated portion of the wafer 60. Thus, the configuration of the detection unit 16 is arbitrary.

As described below, the processing of changing the wafer orientation angle θ_{W} may be performed in the processing chamber 11. Further, the processing of changing the wafer orientation angle θ_{W} may be performed, in addition to the antechamber 11a and the processing chamber 11, in any location. For example, the wafer 60 may be disposed and the wafer orientation angle θ_{W} may be changed at any location separate from the processing unit 10 including the antechamber 11a and the processing chamber 11.

As described above, although the light 31 is a light pulse having, for example, a pulse width of not less than 0.1 ms and not more than 100 ms, the temperature of the wafer 60 increases and decreases due to the wafer 60 being irradiated with the light 31 with about the same duration as the pulse width

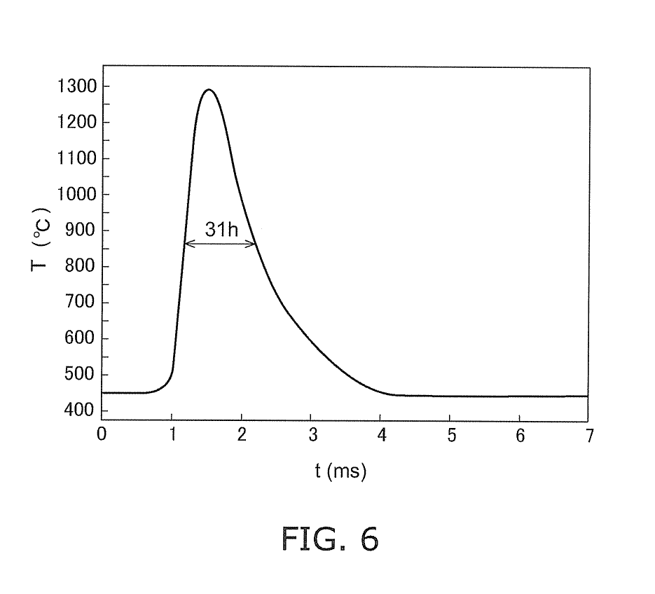

FIG. 6 is a graph illustrating a characteristic of the light of the heat treatment apparatus according to the first embodiment.

In FIG. 6, a time t (milliseconds (ms)) is plotted on the horizontal axis; and a temperature T (° C.) of the wafer 60 irradiated with the light 31 is plotted on the vertical axis. In this specific example, the pulse width of the light 31 emitted by the light emitting unit 30 is about 1 ms.

As illustrated in FIG. 6, the temperature T of the wafer 60 increases due to the irradiation with the light 31 from, for example, 450° C. to the highest value reached of about 1300° C. Then, after, for example, 4 ms, the temperature T returns to the initial temperature. In this specific example, a width 31h at half maximum of the change of the temperature T of the wafer 60 is about 1 ms.

Thus, a temperature increase and decrease steeper than those of an infrared lamp such as a halogen lamp used in conventional RTA can be realized by the light emitting unit 30 using a xenon flash lamp as the lamp 30a. For example, for halogen lamp light, the temperature rise and fall time between 450° C. and 1300° C. is not less than 10 seconds. Specifically, the rise and fall time may be, for example, about 15 seconds. Moreover, the temperature rise and fall time for a temperature difference of 100° C. in the range of 900° C. to 1300° C. is at least 2 to 3 seconds. Conversely, for example, in the case where xenon flash lamp light is used, the temperature rise and fall time between 450° C. and 1300° C. is 0.1 ms to 100 ms. The surface temperature of the wafer 60 may be measured, for example, by a high-speed pyrometer.

Thus, by applying the short time interval of the temperature rise and fall time in which the width 31h at half maximum of the temperature rise and fall of the wafer 60 irradiated with the light 31 is not less than 0.1 ms and not more than 100 ms, a shallow active layer having a low resistance can be formed in the wafer 60 as described below.

In other words, in the case where the width 31h at half maximum is shorter than 0.1 ms, it is difficult for the highest temperature reached by the wafer 60 to be 1000° C. or more; the activation of the implanted impurity is insufficient; and the reduction of the resistance of the wafer 60 is insufficient. On the other hand, in the case where the width 31h at half maximum is longer than 100 ms, the amount of time that the wafer 60 is at high temperatures of 1000° C. or more increases; the thermal diffusion increases; the impurity diffuses to a deep region of the wafer 60; the desired profile of the active layer is not obtained; and it is difficult to form a shallow pn junction proximally to the surface of the wafer 60.

It is more desirable for the width 31h at half maximum of the temperature rise and fall of the wafer 60 irradiated with the light 31 to be not less than 0.5 ms and not more than 50 ms to achieve both a reduced resistance of the active layer and good controllability of the formation of the active layer with high stability.

The pulse width of the light 31 substantially corresponds to the temperature rise and fall time of the wafer 60 irradiated with the light 31. Accordingly, the pulse width of the light 31 is set to be not less than 0.1 ms and not more than 100 ms. More desirably, the pulse width of the light 31 is set to be not less than 0.5 ms and not more than 50 ms. By implementing the second irradiation at a wafer orientation angle θ_{W} different from that of the first irradiation using such a light 31, a shallow active layer having a low resistance can be formed with good uniformity.

The irradiation energy density of the light 31 in the portion of the stage 17 where the wafer 60 is placed may be set, for example, to 10 J/cm² to 100 J/cm².

Such a pulse width and irradiation energy density of the light 31 may be controlled by the control unit 40 by controlling, for example, the power source 32.

During the first irradiation and the second irradiation, the wafer 60 placed on the stage 17 can be supplementally heated, for example, in the range of 300° C. to 700° C. by the heater 18 of the stage 17. It is desirable for the supplemental heating time of the wafer 60 by the heater 18 to be, for example, 10 seconds to 120 seconds. In other words, the supplemental heating may be set to a temperature and duration not to induce thermal stress damage of the wafer 60. In the case where the supplemental heating temperature is lower than 300° C., the thermal stress is suppressed; but it is difficult for the highest temperature reached to be a high temperature of 1000° C. or more. In the case where the supplemental heating temperature is higher than 700° C., the amount of time that the wafer 60 is at high temperatures of 1000° C. or more increases; and it is difficult to form a shallow pn junction proximally to the surface of the wafer 60.

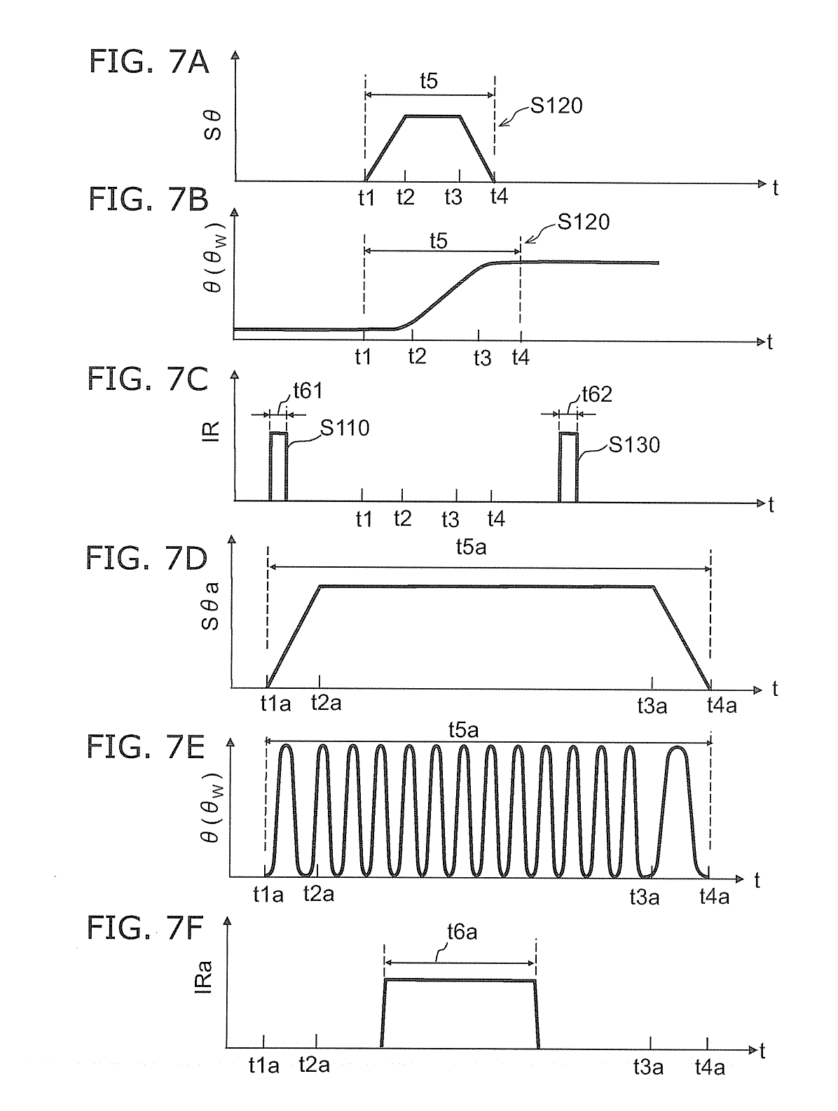

FIGS. 7A to 7F are graphs illustrating operations of the heat treatment apparatus according to the first embodiment and a heat treatment apparatus of a comparative example.

Here, the heat treatment apparatus of the comparative example is an RTA processing apparatus in which light is irradiated while rotating the wafer 60. The duration of the irradiation of the light in the comparative example is, for example, at least 1 second and is an extremely long time compared to the pulse width of the light 31 of the heat treatment apparatus 110 according to this embodiment.

FIGS. 7A to 7C illustrate operations of the heat treatment apparatus 110 according to this embodiment. FIG. 7A illustrates the temporal change of a speed Sθ of the change of the wafer orientation angle θ_{W}. FIG. 7B illustrates the temporal change of the wafer orientation angle θ_{W}. FIG. 7C illustrates the temporal change of an intensity of the light 31. In these drawings, the time t is plotted on the horizontal axis. In FIG. 7A, the speed Sθ is plotted on the vertical axis. In FIG. 7B, the wafer orientation angle θ_{W} is plotted on the vertical axis. In FIG. 7C, an intensity IR of the light 31 is plotted on the vertical axis.

The speed Sθ of the change of the wafer orientation angle θ_{W} may be taken to be, for example, an angular velocity. In other words, in the case where the wafer 60 is placed on the antechamber stage 17a and the wafer orientation angle θ_{W} is changed by rotating the antechamber stage 17a, the angular velocity of the rotation of the antechamber stage 17a may be taken to be the speed Sθ. Also, as described below, in the case where the wafer orientation angle θ_{W} is changed with the wafer 60 disposed in the interior of the processing chamber 11, the speed Sθ may be taken to be the angular velocity of the rotation of the wafer disposition control unit 20 performing the change.

On the other hand, FIGS. 7D to 7F illustrate operations of the heat treatment apparatus of the comparative example. FIG. 7D illustrates the temporal change of a speed Sθa of the rotation of the wafer 60. FIG. 7E illustrates the temporal change of the wafer orientation angle θ_{W}. FIG. 7F illustrates the temporal change of the intensity of the light. In these drawings, the time t is plotted on the horizontal axis. In FIG. 7D, the speed Sθa is plotted on the vertical axis. In FIG. 7E, the wafer orientation angle θ_{W} is plotted on the vertical axis. In FIG. 7F, an intensity IRa of the light is plotted on the vertical axis.

In the heat treatment apparatus 110 according to this embodiment, first, the light 31 is irradiated for a duration t61 as illustrated in FIG. 7C. In other words, step S110 is implemented.

Subsequently, the disposition of the wafer 60 (e.g., the wafer orientation angle θ_{W}) is changed in step S120.

At this time, as illustrated in FIGS. 7A and 7B, the wafer orientation angle θ_{W} starts to change from a time t1 and finishes changing at a time t4.

In such a case, as illustrated in FIG. 7A, the speed Sθ increases from the time t1 to a time t2, is constant from the time t2 to a time t3, and decreases from the time t3 to the time t4.

In other words, in a wafer disposition control unit 20 such as, for example, the antechamber stage 17a, the speed Se is low when the rotating starts and reaches the maximum speed after a constant time interval (the time t1 to the time t2). A constant time interval (the time t3 to the time t4) is necessary for the speed Sθ to decrease at the end of the rotation.

Therefore, as illustrated in FIG. 7B, the wafer orientation angle θ_{W} slowly changes during the initial stage from the time t1 to the time t2, changes relatively rapidly during the subsequent stage from the time t2 to the time t3, and again changes slowly during the final stage from the time t3 to the time t4. The change of the wafer orientation angle θ_{W} is less than 360 degrees (plus or minus 180 degrees).

The change of the wafer orientation angle θ_{W} has such a temporal characteristic. That is, the time necessary to change the wafer orientation angle θ_{W} is a time interval t5 from the time t1 to the time t4.

After implementing step S120 recited above, the light 31 is irradiated for the duration t62. In other words, step S130 is implemented.

In the heat treatment apparatus 110 according to this embodiment, the durations of the first irradiation and the second irradiation, i.e., the duration t61 and the duration t62 recited above, are shorter than the time (the time interval t5) necessary to change the disposition (the wafer orientation angle θ_{W}) of the wafer.

On the other hand, in the case of conventional RTA processing of the heat treatment apparatus of the comparative example, the surface temperature distribution of the wafer 60 is made uniform by irradiating the wafer 60 with the light while rotating the wafer 60 at a constant speed.

In other words, as illustrated in FIG. 7D, the speed Sea of the rotation of the wafer increases from a time t1a, reaches a maximum speed during an interval from the time t1a to a time t2a, and decreases from a time t3a. The rotation ends at a time t4a.

As illustrated in FIG. 7E, the wafer 60 rotates during a time interval t5a from the time t1a to the time t4a; and the value of the wafer orientation angle θ_{W} repeatedly goes from 0 degrees to 360 degrees.

As illustrated in FIG. 7F, the light is irradiated during the rotation of the wafer 60. In such a case, a time interval t6a of the irradiation of the light is longer than the time necessary for one rotation of the wafer 60. Here, the disposition of the wafer returns to the initial disposition every rotation of 360 degrees. Therefore, when the wafer 60 multiply rotates, a rotation of less than 360 degrees is substantially the change of the disposition. In the heat treatment apparatus of the comparative example, the light is irradiated for a duration longer than the time necessary for the changing of the disposition, i.e., the rotation of less than 360 degrees. Thus, in the comparative example, the light is irradiated for a duration longer than the time interval of one rotation (360 degrees) of the wafer 60.

On the other hand, in the heat treatment which is the object of the invention, the light 31 having an extremely short pulse width is used to form a shallow active layer having a low resistance. Therefore, it is practically difficult for the wafer 60 to be rotated 360 degrees or more during one irradiation with the light 31. For example, in the case where the wafer 60 is rotated, the rotational speed is increased for a constant time interval, subsequently reaches a maximum, and subsequently decreases for a constant time interval. However, even while the rotational speed is at the maximum, the time interval of the irradiation of the light 31 is shorter than the time necessary for one rotation. Therefore, unevenness of the temperature of the wafer 60 occurs over the surface. In other words, within the extent of practical apparatus design, it is difficult to rotate the wafer 60 one rotation or more within the duration of the irradiation of the light 31.

Conversely, in the heat treatment apparatus 110 according to this embodiment, unevenness of the temperature of the wafer 60 over the surface is suppressed by performing multiple irradiations having mutually different wafer orientation angles θ_{W}, i.e., dispositions of the wafer. In such a case, the change of the wafer orientation angle θ_{W} is less than 360 degrees. In other words, the duration t61 and the duration t62 of the first irradiation and the second irradiation are shorter than the time (the time interval t5) necessary to change the disposition (the wafer orientation angle θ_{W}) of the wafer.

The duration t61 and the duration t62 of the first irradiation and the second irradiation are shorter than, for example, the time necessary for one rotation of the wafer 60 at the maximum speed Sθ (the speed Sθ from the time t2 to the time t3) of the change of the wafer orientation angle θ_{W}. In this specific example, the duration t61 and the duration t62 are not less than 0.1 ms and not more than 100 ms.

Thereby, unevenness of the temperature of the wafer 60 over the surface can be suppressed within the extent of practical apparatus design by using the light 31 having a short pulse width capable of forming a shallow active layer having a low resistance.

One example of a method for manufacturing a semiconductor device including the heat treatment of the wafer 60 using the heat treatment apparatus 110 according to this embodiment will now be described.

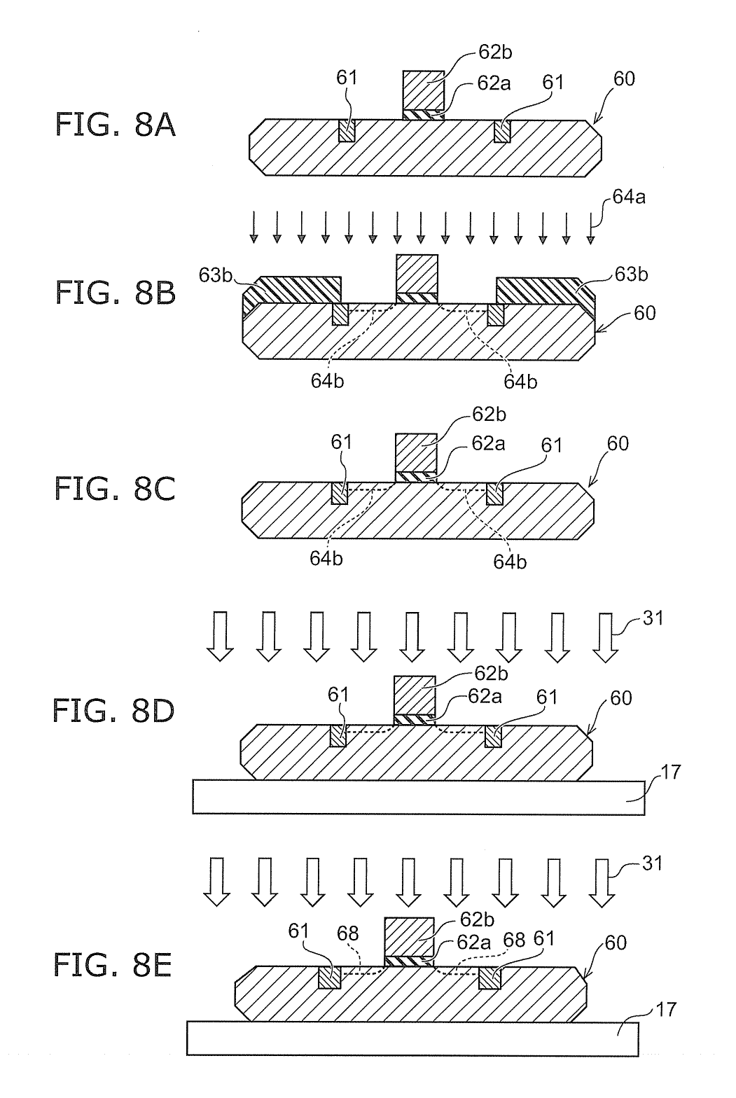

FIGS. 8A to 8E are schematic cross-sectional views in order of the processes, illustrating the method for manufacturing the semiconductor device using the heat treatment apparatus according to the first embodiment.

For simplification, a portion will now be described in which one MOS transistor is formed on a major surface of the wafer 60.

As illustrated in FIG. 8A, an element separation region 61, a gate insulating film 62a, and a gate electrode 62b are formed on the major surface of the wafer 60 made of, for example, a semiconductor such as silicon.

The wafer 60 may include, for example, a bulk monocrystalline silicon wafer, an epitaxial wafer, an SOI (Silicon On Insulator) wafer, and the like.

Then, as illustrated in FIG. 8B, a resist film 63b having a prescribed patterned configuration is formed by photolithography. An impurity implantation layer 64b is formed by using the resist film 63b and the gate electrode 62b as a mask and implanting an impurity ion 64a by, for example, ion implantation into a region of the major surface of the wafer 60 forming, for example, a source-drain extension region.

Then, as illustrated in FIG. 8C, the resist film 63b is removed by peeling.

Continuing as illustrated in FIG. 8D, the wafer 60 is placed on the stage 17 of the heat treatment apparatus 110 at the first wafer orientation angle θ_{W1}; and the first irradiation is performed to irradiate with the light 31. At this time, the wafer 60 is supplementally heated by the heater 18 of the stage 17 to a temperature in the range of, for example, about 300° C. to 700° C. At this time, by appropriately controlling, for example, the inner heater 18a and the outer heater 18b provided in the stage 17, the temperature of the wafer 60 can be controlled to be within a constant range in the direction from the center of the wafer 60 to the outer circumference; and the temperature distribution of the wafer along the direction from the center of the wafer 60 toward the outer circumference can be set within the desired range. Utilizing the gas inlet 11i and the gas outlet 11o, the processing chamber 11 can be filled with, for example, an inert gas and the like such as nitrogen gas and argon gas. In this state, the wafer 60 is irradiated with the light 31; and the upper face of the wafer 60 is heated for 0.1 ms to 100 ms. For example, the energy density of the light 31 is 25 J/cm² on the upper face of the wafer 60.

By such a first irradiation, the temperature of the upper face of the wafer 60 increases to 1100° C. or more. By such a heat treatment, the first activation is implemented substantially without diffusion of the impurity of the impurity implantation layer 64b.

Subsequently, as described above, the wafer orientation angle θ_{W} is set to the second wafer orientation angle θ_{W2}.

Then, as illustrated in FIG. 8B, the second irradiation is performed to irradiate the wafer 60 placed on the stage 17 at the second wafer orientation angle θ_{W2} with the light 31. Except for the changing of the wafer orientation angle θ_{W} of the wafer 60, the conditions of the second irradiation may be, for example, the same conditions as those of the first irradiation. By the second irradiation, a second activation is implemented substantially without diffusion of the impurity of the impurity implantation layer 64b. Thereby, a shallow active layer 68 having a low resistance is formed. At this time, the depth of the active layer 68 from the upper face of the wafer 60 is, for example, not more than 20 nm (nanometers).

Thus, by performing the second irradiation at a different wafer orientation angle θ_{W} of the wafer 60 than that of the first irradiation, the surface temperature distribution of the wafer 60 of the first irradiation is compensated; a uniform temperature history can be obtained in the major surface of the wafer 60; and the shallow active layer 68 having a low resistance can be formed.

In other words, by the heat treatment apparatus 110 and the manufacturing method recited above, the shallow active layer 68 having a low resistance, which is difficult using conventional RTA processing, can be uniformly formed.

Thus, by performing ultra rapid heat treatment with reduced temperature fluctuation in the surface, a shallow active layer having a low resistance can be formed with good uniformity.

The resistance value of the active layer 68 is determined by the irradiation of the light 31 and the temperature of the wafer 60 based on the heating by the stage 17. A higher temperature of the wafer 60 reduces the resistance value.

The impurity ion 64a implanted into the wafer 60 illustrated in FIG. 8B may include various ions such as boron ions, phosphorus ions, and arsenic ions.

An example of a method for manufacturing a CMOS transistor forming an element of an LSI of a semiconductor device will now be described as another example of a method for manufacturing a semiconductor device including processing of the wafer 60 using the heat treatment apparatus 110 according to this embodiment.

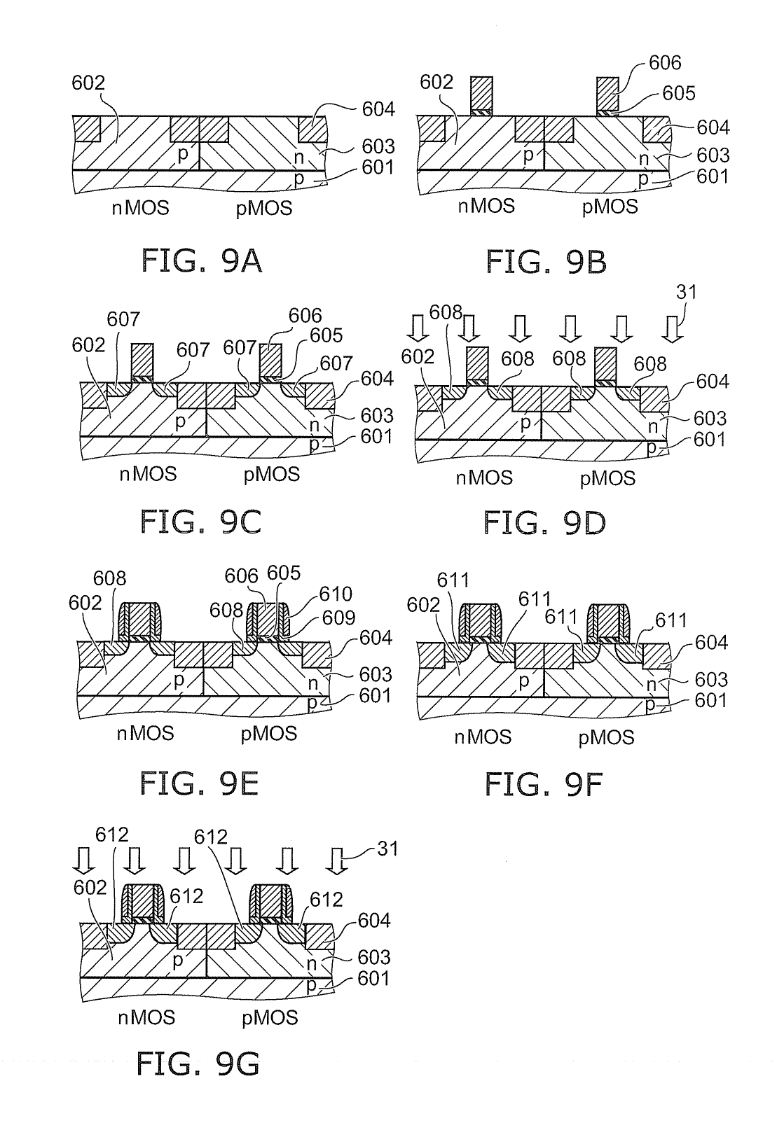

FIGS. 9A to 9G are schematic cross-sectional views in order of the processes, illustrating another method for manufacturing the semiconductor device using the heat treatment apparatus according to the first embodiment.

First, as illustrated in FIG. 9A, a p-well layer 602 is formed in, for example, an nMOS region of a p-type silicon substrate 601 (a wafer); and an n-well layer 603 is formed in a pMOS region. An element separation region 604 is formed around the p-well layer 602 and around the n-well layer 603.

Then, as illustrated in FIG. 9B, a silicon oxide film forming a gate insulating film 605 is formed on the p-well layer 602, the n-well layer 603, and the element separation region 604. Thereupon, a polycrystalline silicon film forming a gate electrode 606 is formed. Then, the polycrystalline silicon film and the silicon oxide film recited above are selectively etched by, for example, RIE (Reactive Ion Etching) to form the gate electrode 606 and the gate insulating film 605.

Continuing as illustrated in FIG. 9C, ion implantation is performed using the gate electrode 606 as a mask.

In other words, As, for example, is implanted as a group V atom forming an n-type impurity by ion implantation into the surface of the p-well layer 602 of the exposed nMOS region by, for example, masking the pMOS region with a photoresist film. The conditions of the As ion implantation include, for example, an acceleration energy of 2 keV and a dose of 1×10¹⁵ cm⁻².

Then, the photoresist film of the pMOS region is removed; and B, for example, is implanted as a group III atom forming a p-type impurity by ion implantation into the surface of the n-well layer 603 of the exposed pMOS region by masking the nMOS region with a photoresist film. The conditions of the B ion implantation may include, for example, an acceleration energy of 0.5 keV and a dose of 1×10¹⁵ cm⁻².

Thus, a first impurity implantation layer 607 is formed in the p-well layer 602 and the n-well layer 603 between the element separation region 604 and each of the ends of the gate insulating film 605 with a depth of about 12 nm from the surface.

Then, as illustrated in FIG. 9D, heat treatment is performed by the heat treatment apparatus 110. Specifically, after removing the photoresist film recited above of the nMOS region, the silicon substrate 601 is placed on the stage 17 of the heat treatment apparatus 110; and heat treatment for activation is performed. In the heat treatment, the silicon substrate 601 is supplementally heated from the backside by the heater 18 of the stage 17 to, for example, 500° C. While maintaining the temperature of the silicon substrate 601 at the supplemental heating temperature of 500° C., the silicon substrate 601 is irradiated from the upper side with the light 31 from the light emitting unit 30.

In such a case, as described above, the first irradiation, the changing of the wafer orientation angle θ_{W} of the silicon substrate 601, i.e., the wafer, and the second irradiation using the changed wafer orientation angle θ_{W} are implemented. In the first irradiation and the second irradiation, the pulse width of the light 31 is, for example, 1 ms and the irradiation energy is, for example, 25 J/cm².

By the activation heat treatment, the As and the B implanted into the first impurity implantation layer 607 are activated by being taken into lattice positions by substitution. Thereby, an n-type or a p-type first active layer 608 is formed between the element separation region 604 and either end of the gate insulating film 605.

Then, as illustrated in FIG. 9E, a silicon oxide film and a silicon nitride film forming a first side wall spacer 609 and a second side wall spacer 610, respectively, are sequentially deposited by, for example, LPCVD (Low Pressure Chemical Vapor Deposition). The first side wall spacer 609 and the second side wall spacer 610 are formed by performing etching of the silicon oxide film and the silicon nitride film by RIE to selectively leave the silicon oxide film and the silicon nitride film on the side faces of the gate electrode 606 and the gate insulating film 605.

Continuing as illustrated in FIG. 9F, the gate electrode 606, the first side wall spacer 609, and the second side wall spacer 610 are used as a mask to perform ion implantation by a method similar to the method described in regard to FIG. 9C.

Namely, ion implantation of As, for example, as a group V atom forming an n-type impurity is performed into the surface of the p-well layer 602. At this time, the As ion implantation conditions may include, for example, an acceleration energy of 20 keV and a dose of 4×10¹⁵ cm⁻². Then, ion implantation of B, for example, as a group III atom forming a p-type impurity is performed into the surface of the n-well layer 603. The B ion implantation conditions include, for example, an acceleration energy of 2 keV and a dose of 4×10¹⁵ cm⁻². Thereby, a second impurity implantation layer 611 forming a source/drain region is formed in the interior of the silicon substrate 601 in contact with the element separation region 604 apart from the end portions of the gate electrode 606. The second impurity implantation layer 611 is formed in regions of the p-well layer 602 and the n-well layer 603 deeper from the surface than the first impurity implantation layer 607.

In these ion implantations, corresponding impurity ions are implanted also into the gate electrode 606.

Then, as illustrated in FIG. 9G, heat treatment is implemented by the heat treatment apparatus 110. Specifically, the silicon substrate 601 is placed on the stage 17; the silicon substrate 601 is supplementally heated from the backside of the silicon substrate 601 by the heater 18 to, for example, 500° C.; and the silicon substrate 601 is irradiated from the upper side of the silicon substrate 601 with the light 31 of the light emitting unit 30.

In such a case, as described above, the first irradiation, the changing of the wafer orientation angle θ_{W} of the silicon substrate 601, i.e., the wafer, and the second irradiation using the changed wafer orientation angle θ_{W} are implemented. In the first irradiation and the second irradiation, the pulse width of the light 31 is, for example, 1 ms and the irradiation energy is, for example, 25 J/cm².

By the activation heat treatment, the As and the B implanted into the second impurity implantation layer 611 are activated by being taken into lattice positions by substitution. Thereby, an n-type or a p-type second active layer 612 is formed between the element separation region 604 and either end of the gate insulating film 605. The second active layer 612 is formed in regions of the p-well layer 602 and the n-well layer 603 deeper from the surface than the first active layer 608.

Thereafter, an inter-layer insulating film such as a silicon oxide film is formed to cover the p-well layer 602, the n-well layer 603, the gate electrode 606, the first side wall spacer 609, and the second side wall spacer 610; contact holes are made in the inter-layer insulating film on the gate electrode 606 and on the p-type second active layer 612 corresponding to the source/drain region; and interconnects are connected to the gate electrode 606 and the p-type second active layer 612 via the respective contact holes. Thus, the semiconductor device can be manufactured.

Thus, in the semiconductor device manufactured using the heat treatment apparatus 110 according to this embodiment, an ultra rapid heat treatment can be implemented with reduced temperature fluctuation in the surface. Thereby, a shallow active layer with a low resistance can be formed with good uniformity; and a high performance semiconductor device can be manufactured with high productivity.

In other words, the process window enlarges also for the multiple semiconductor chips disposed in the major surface of the silicon substrate 601 (the wafer 60); and a high yield high performance fine MOSFET having stable electrical characteristics can be easily manufactured.

Although, in the manufacturing method recited above, the first heat treatment forming the first active layer 608 from the first impurity implantation layer 607 and the second heat treatment forming the second active layer 612 from the second impurity implantation layer 611 are implemented; and in both of the heat treatments, a first processing and a second processing using a different wafer orientation angle θ_{W} than that of the first processing are implemented; the invention is not limited thereto.

For example, in the first heat treatment forming the first active layer 608 from the first impurity implantation layer 607, the first irradiation may be performed at the first wafer orientation angle θ_{W1}; and in the second heat treatment forming the second active layer 612 from the second impurity implantation layer 611, the second irradiation may be performed at the second wafer orientation angle θ_{W2}. Thus, in the case where the wafer 60 is multiply irradiated with the light 31, the wafer orientation angle θ_{W} may be changed for each of the irradiations.

Also, for example, the heat treatment apparatus 110 according to this embodiment may be used and the manufacturing method according to the embodiment of the invention described in regard to FIG. 2 may be applied to at least one selected from the first heat treatment forming the first active layer 608 from the first impurity implantation layer 607 and the second heat treatment forming the second active layer 612 from the second impurity implantation layer 611.

In other words, for example, in the first heat treatment, a heat treatment by spike RTA using a conventional halogen lamp may be implemented. In such a case, it is favorable to use heat treatment at a lower temperature with a focus more on defect recovery than activation to suppress the diffusion of the first impurity implantation layer 607, that is, a heat treatment temperature at least lower than the annealing temperature assumed for a flash lamp annealing.

For example, in the second heat treatment, a heat treatment by spike RTA using a conventional halogen lamp may be implemented. In such a case as well, it is favorable to use heat treatment at a lower temperature, that is, a heat treatment temperature at least lower than the annealing temperature assumed for a flash lamp annealing.

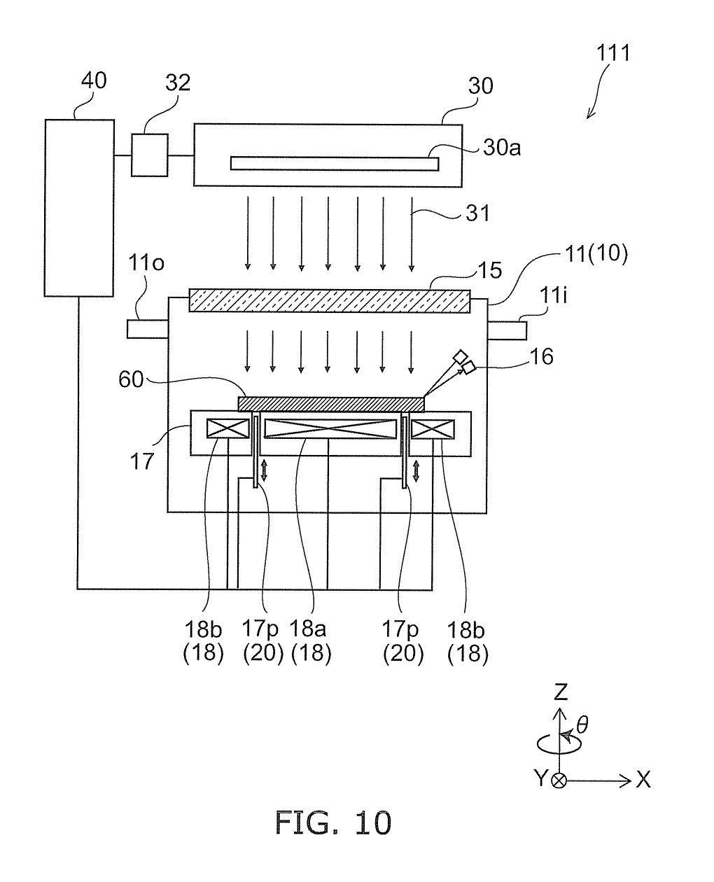

FIG. 10 is a schematic view illustrating the configuration of another heat treatment apparatus according to the first embodiment.

In another heat treatment apparatus 111 according to this embodiment, a pin 17p is provided in the processing chamber 11 of the processing unit 10 as illustrated in FIG. 10 as the wafer disposition control unit 20 capable of changing the orientation angle of the wafer 60, i.e., the wafer orientation angle θ_{W}.

The pin 17p is provided in a portion of a gap between, for example, the inner heater 18a and the outer heater 18b of the stage 17. The pin 17p and the stage 17 are designed to be movable relative to each other. In other words, the pin 17p and the stage 17 are movable relative to each other in the vertical direction (the Z axis direction). Further, the relative dispositions of the pin 17p and the stage 17 are designed to be rotatable around the Z axis direction.

For example, the upper end of the pin 17p can support the wafer 60 when the upper end of the pin 17p is positioned above the upper face (e.g., the major surface) of the stage 17. Then, for example, the wafer 60 is placed on the upper face of the stage 17 when the upper end of the pin 17p is positioned below the upper face of the stage 17.

The gap provided, for example, between the inner heater 18a and the outer heater 18b is provided along a circumference centered on the center of the stage. Thereby, the stage 17 (the inner heater 18a and the outer heater 18b) and the pin 17p are designed to have an angle of the relative disposition which is changeable along the gap.

Thus, the stage 17 (the stage section) includes the inner heater 18a opposing the central portion of the wafer 60 and the outer heater 18b provided around the inner heater 18a; and the pin 17p (the wafer disposition control unit 20) is provided in the gap between the inner heater 18a and the outer heater 18b. The pin 17p is movable along a direction perpendicular to the major surface of the stage 17. The pin 17p is movable along a circumference centered on the central portion of the stage 17 in the gap.

By using such a pin 17p, for example, the upper end of the pin 17p may be positioned below the upper face of the stage 17; the wafer 60 is placed on the upper face of the stage 17 in the first wafer orientation angle θ_{W1}; the first irradiation is implemented; subsequently, the upper end of the pin 17p is positioned above the upper face of the stage 17; the upper end of the pin 17p supports the wafer 60; and the wafer 60 is moved away from the upper face of the stage 17. Then, in this state, the wafer orientation angle θ_{W} of the wafer 60 is changed with the pin 17p to the second wafer orientation angle θ_{W2}.

Then, the upper end of the pin 17p is again positioned below the upper face of the stage 17; the wafer 60 is placed on the upper face of the stage 17 at the second wafer orientation angle θ_{W2}; and the second irradiation is implemented.

Thus, it is advantageous to provide the pin 17p (the wafer disposition control unit 20) in the processing chamber 11 of the processing unit 10 because the wafer orientation angle θ_{W} of the wafer 60 can be changed in the interior of the processing chamber 11 after the first processing and therefore the time necessary for heat treatment can be shortened.

Such an operation of the pin 17p and the stage 17, that is, the operation of controlling the wafer orientation angle θ_{W}, may be performed, for example, by the control unit 40. For example, a control program stored in the control unit 40 may cause the pin 17p and the stage 17 to move relative to each other in the Z axis direction and may include a program (an operation recipe) regarding the operation of rotating.

Thus, in the case where the processing of changing the wafer orientation angle θ_{W} of the wafer 60 is performed in the processing chamber 11, the detection unit 16 described above may be provided in the processing chamber 11.

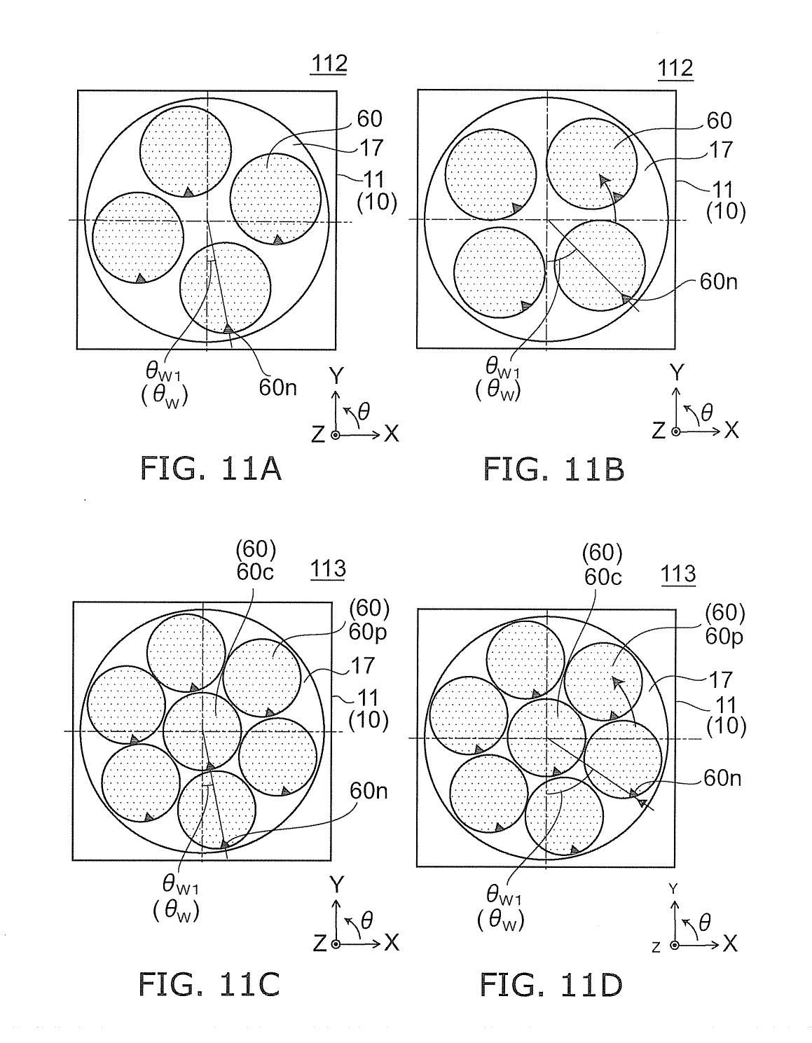

FIGS. 11A to 11D are schematic views illustrating operations of other heat treatment apparatuses according to the first embodiment.

Namely, FIGS. 11A and 11B illustrate the configuration and operation of another heat treatment apparatus 112. FIGS. 11C and 11D illustrate the configuration and operation of yet another heat treatment apparatus 113. FIGS. 11A and 11C illustrate the disposition of the wafers 60 during the first irradiation. FIGS. 11B and 11D illustrate the disposition of the wafers 60 during the second irradiation.

In the heat treatment apparatus 112, four of the wafers 60 are placed on the stage 17 as illustrated in FIGS. 11A and 11B. The first irradiation and the second irradiation are performed collectively for these four wafers 60. In such a case as well, the disposition of the wafers 60 is changed from that of the first irradiation, and the second irradiation is performed. In other words, the wafer orientation angle θ_{W}, which is an orientation angle of the wafers 60 relative to the processing unit 10 having an axis in a direction perpendicular to the major surface of the wafers 60, is changed from that of the first irradiation, and the second irradiation is performed.

For example, multiple wafers 60 may be placed on the major surface of the stage 17; and the changing recited above after the first irradiation may include changing the relative disposition of the multiple wafers 60 with respect to the processing unit 10.

However, for example, in such a case, the disposition of the four wafers 60 may be rotated around the center (i.e., the center of the stage 17) of the disposition of the four wafers 60.

In other words, in such a case, the wafer orientation angle θ_{W} of each of the wafers 60 may be taken as the relative angle between a prescribed reference of the processing unit 10 and a line connecting, for example, the notch portion 60n forming a reference of the wafer 60 and the center of the disposition of the four wafers 60. In such a case as well, the wafer orientation angle θ_{W} of the wafer 60 can be changed between the first irradiation and the second irradiation.

In other words, although the wafer 60 rotates around the center (i.e., the center of the stage 17) of the wafer 60 to change the wafer orientation angle θ_{W} in the case where the wafer 60 is disposed on the stage 17 in a state in which the center of the wafer 60 matches the center of the stage 17 as illustrated in FIGS. 3A to 3E, the wafer 60 rotates not around the center of the wafer 60 but around the center of the stage 17 in the case where the center of the wafer 60 is disposed in a portion other than the center of the stage 17 as illustrated in FIGS. 11A and 11B. However, in such a case as well, the wafer orientation angle θ_{W} is a relative orientation angle of the wafer 60 with respect to the processing unit 10 having an axis in a direction perpendicular to the major surface of the wafer 60; the wafer orientation angle θ_{W} can be changed from that of the first irradiation; and the second irradiation can be performed.

Thus, the reference of the wafer orientation angle θ_{W} of the wafer 60 may change with the relative relationship between the disposition of the wafer 60 and the reference of the processing unit 10.

For example, in the heat treatment apparatus 113, seven wafers 60 are placed on the stage 17 as illustrated in FIGS. 11C and 11D. In other words, one central wafer 60c is disposed in the central portion of the stage 17; and six peripheral wafers 60p are disposed in the peripheral portion of the stage 17. The first irradiation and the second irradiation are performed collectively for the seven wafers 60.

In such a case as well, the disposition of the wafer 60 can be changed from that of the first irradiation, and the second irradiation can be performed. In other words, the wafer orientation angle θ_{W} is a relative orientation angle of the wafer 60 with respect to the processing unit 10 having an axis in a direction perpendicular to the major surface of the wafer 60; the wafer orientation angle θ_{W} can be changed from that of the first irradiation; and the second irradiation can be performed.

However, in such a case, the wafer orientation angle θ_{w} of the central wafer 60c is changed by the central wafer 60c rotating around the center of the central wafer 60c. The peripheral wafer 60p rotates around the center of the stage 17.

For such a central wafer 60c and the peripheral wafers 60p as well, the wafer orientation angle θ_{W} is a relative orientation angle with respect to the processing unit 10 having an axis in a direction perpendicular to the major surface of the wafer 60; the wafer orientation angle θ_{W} can be changed from that of the first irradiation; and the second irradiation can be performed.

Although the case is described above in which two irradiations, i.e., the first irradiation and the second irradiation, are performed, the invention is not limited thereto. In other words, it is sufficient for multiple irradiations to be implemented at mutually different wafer orientation angles θ_{W}; and the number of irradiations is arbitrary. In the case of multiple irradiations, the wafer orientation angle θ_{W} may be appropriately set according to the number of irradiations to obtain a uniform temperature history of the wafer 60 over the major surface of the wafer 60.

Operations of the heat treatment apparatus in the case where heat treatment of multiple wafers is performed will now be described.

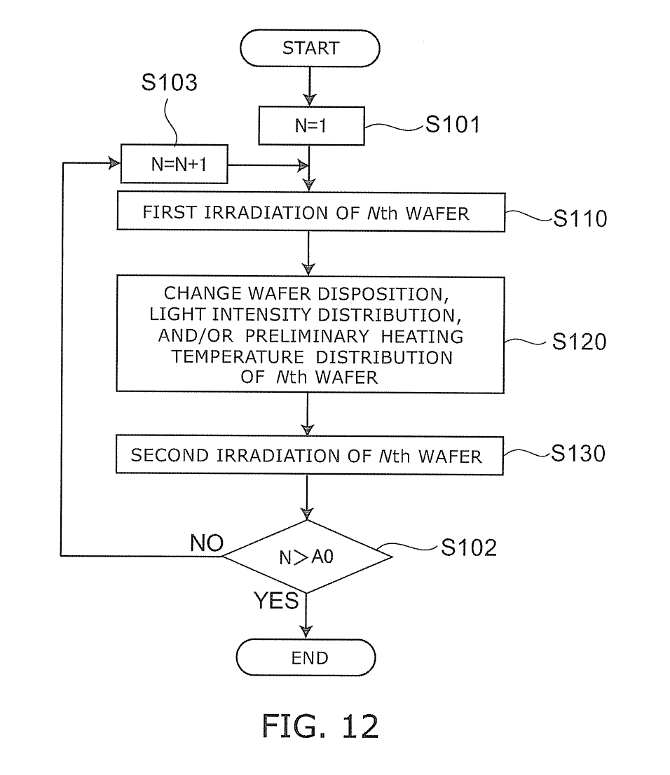

FIG. 12 is a flowchart illustrating another operation of the heat treatment apparatus according to the first embodiment.

As illustrated in FIG. 12, in this specific example, the processing of step S110 to step S130 is performed continuously for each of the wafers 60.

For example, first, an integer N is set to 1 (step S101) and the first irradiation of the Nth wafer 60 is performed (step S110). Continuing, the disposition of the Nth wafer 60 (the wafer orientation angle θ_{W}) is changed (step S120). Then, the second irradiation of the Nth wafer 60 is performed (step S130).

Subsequently, the integer N is compared to a prescribed number A0 (step S102). The flow ends if the integer N is greater than the number A0. In the case where the integer N is not more than the number A0, the integer N is increased by 1 (step S103), the flow returns to step S110, and the flow recited above repeats.

Step S120 recited above, as described below, may be taken to be the processing of changing at least one selected from the disposition of the Nth wafer 60 (e.g., the wafer orientation angle θ_{W}), the distribution of the intensity (e.g., the orientation angle dependency of the intensity) of the light 31, and the distribution of a preliminary heating temperature (e.g., the orientation angle dependency of the preliminary heating temperature).

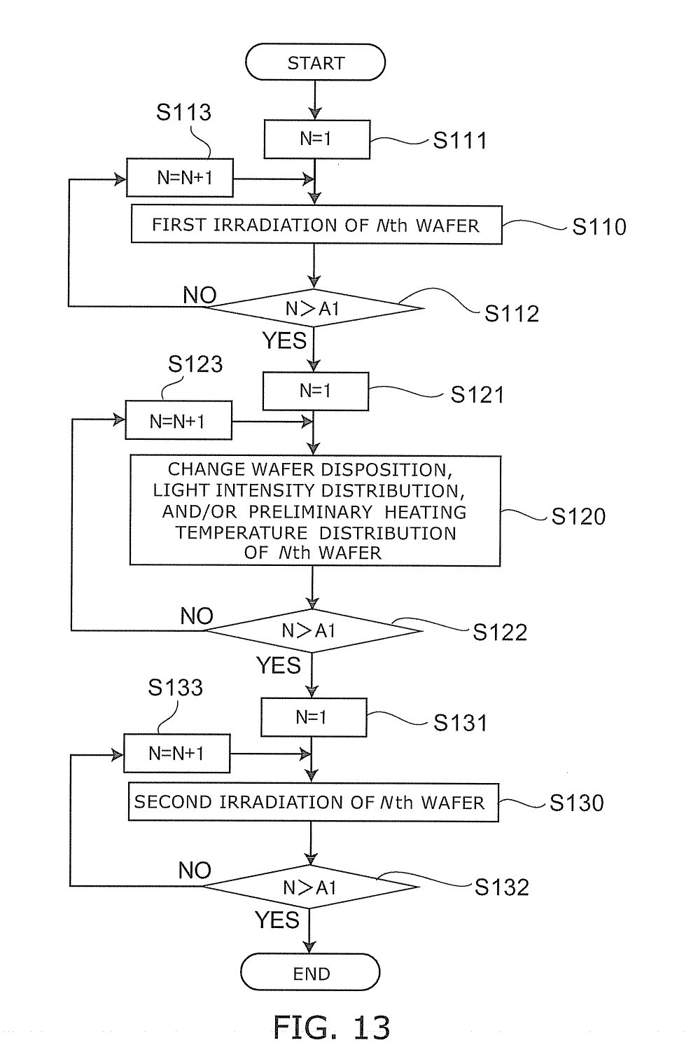

FIG. 13 is a flowchart illustrating another operation of the heat treatment apparatus according to the first embodiment.

In this specific example, each processing of step S110, step S120, and step S130 is implemented for the multiple wafers 60 in batches as illustrated in FIG. 13.

For example, first, the integer N is initialized by being set to 1 (step S111); the first irradiation of the Nth wafer 60 is performed (step S110); the integer N is compared to a prescribed number A1 (step S112); and the flow ends if the integer N is greater than the number A1. In the case where the integer N is not more than the number A1, the integer N is increased by 1 (step S113), the flow returns to step S110, and the flow recited above repeats. Thereby, step S110 is performed for a batch of the multiple wafers 60.

Subsequently, step S120 is performed for the batch of the multiple wafers 60 by similarly performing step S121, step S120, step S122, and step S123.

Further, step S130 is performed for the batch of the multiple wafers 60 by similarly performing step S131, step S130, step S132, and step S133.

Thereby, in the case where heat treatment is performed, for example, for multiple wafers 60 of one cassette, first, step S110 is performed on the wafers 60 of the one cassette. Subsequently, step S120 is performed for the wafers 60 of the batch. Then, step S130 is performed for the wafers 60 of the batch.

The processing of steps S110, S120, and S130 may be performed for multiple cassettes in one batch instead of for a one-cassette batch.

Step S120 recited above, as described below, may be taken to be the processing of changing at least one selected from the disposition (e.g., the wafer orientation angle θ_{W}) of the Nth wafer 60, the distribution of the intensity (e.g., the orientation angle dependency of the intensity) of the light 31, and the distribution of the preliminary heating temperature (e.g., the orientation angle dependency of the preliminary heating temperature).

### Second Embodiment

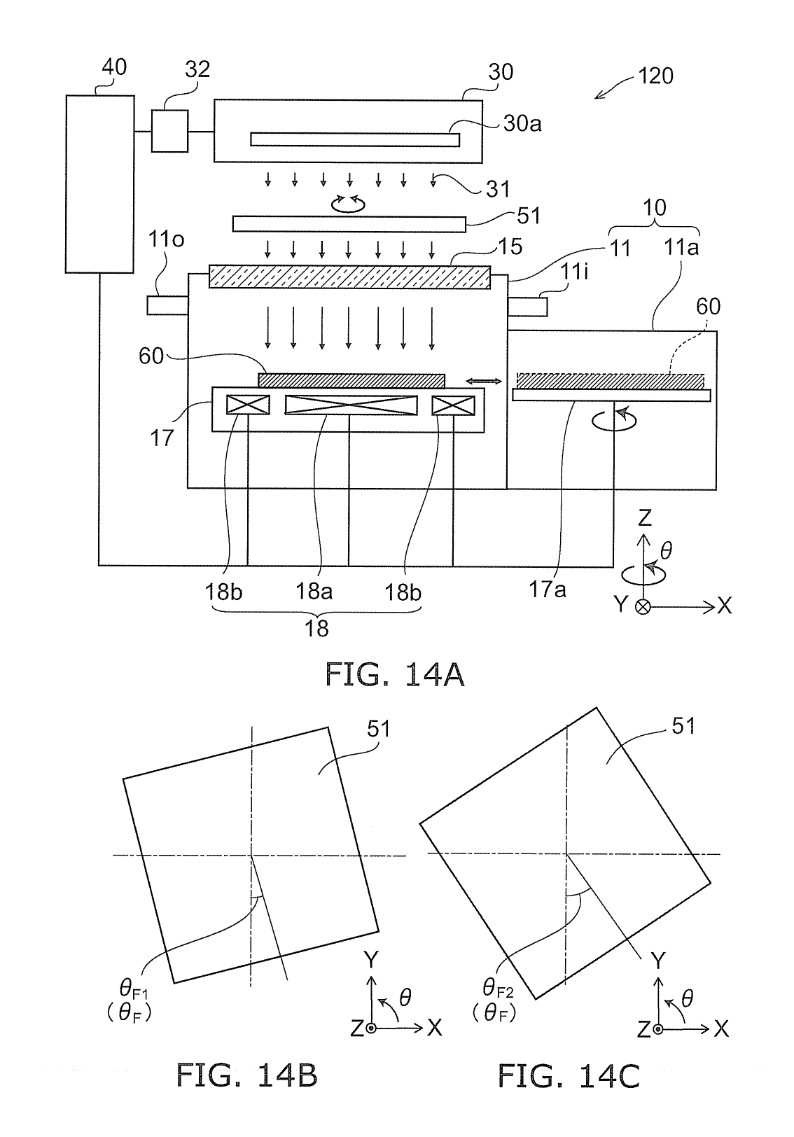

FIGS. 14A to 14C are schematic views illustrating the configuration and operations of a heat treatment apparatus according to a second embodiment. Namely, FIG. 14A illustrates the configuration of a heat treatment apparatus 120. FIGS. 14B and 14C illustrate operations during a first processing and a second processing, respectively.

In the heat treatment apparatus 120 according to the second embodiment of the invention, a filter 51 is provided between the stage 17 and the light emitting unit 30 to attenuate the light 31 as illustrated in FIG. 14A.

After the first irradiation, the distribution of the intensity of the light 31 on the major surface of the stage 17 is changed using the filter 51, and the second irradiation is performed. In other words, for example, the orientation angle dependency of the intensity of the light 31 having an axis in a direction perpendicular to the major surface of the stage 17 is changed, and the second irradiation is performed. At this time, the axis may be a direction perpendicular to the major surface of the stage 17 that passes through the center of the major surface of the stage 17.

For example, as illustrated in FIG. 14B the orientation angle (a filter orientation angle θ_{F}) of the filter 51 is set to a first filter orientation angle θ_{F1} during the first irradiation. By performing the first irradiation in this state, a surface temperature distribution of the wafer 60 such as, for example, that described in regard to FIG. 3B, i.e., a surface temperature distribution having large fluctuation, is obtained.

At this time, after the first irradiation, the filter orientation angle θ_{F} is changed and set to a second filter orientation angle θ_{F2} as illustrated in FIG. 14C. In the case where the second irradiation is implemented in this state, as a result, the surface temperature history distribution of the wafer 60 is compensated; and a uniform temperature history in the surface of the wafer 60 can be obtained.

In other words, by changing the distribution (e.g., the orientation angle dependency) of the intensity of the light 31 between the first irradiation and the second irradiation, an ultra rapid heat treatment having reduced temperature fluctuation in the surface can be implemented.

Although the case is illustrated in FIGS. 14A to 14C where the configuration of the major surface of the filter 51 is rectangular, the configuration of the filter 51 is arbitrary.

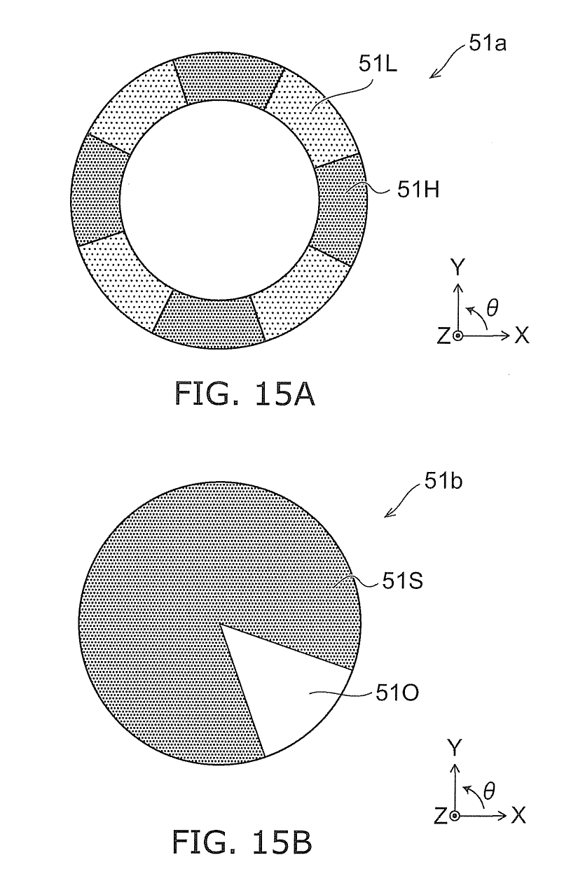

FIGS. 15A and 15B are schematic views illustrating filters usable in the heat treatment apparatus according to the second embodiment.

As illustrated in FIG. 15A, a filter 51a usable in the heat treatment apparatus 120 according to this embodiment includes a high transmittance region 51H and a low transmittance region 51L.

In other words, the filter 51a includes multiple regions (the high transmittance region 51H and the low transmittance region 51L) having mutually different transmittances of the light 31 disposed along a circumference (the circumferential edge direction of the filter) centered on the center of the major surface of the filter 51a. That is, the filter 51a has a plurality of regions having different transmittances with respect to the light along a circumferential edge direction of the filter 51a.

In this specific example, four of each of the high transmittance region 51H and the low transmittance region 51L are disposed such that the orientation angles θ are 90 degrees apart and the difference from the orientation angle θ of the high transmittance region 51H to the orientation angles θ of adjacent low transmittance regions 51L is 45 degrees.

The filter 51a may include, for example, quartz glass. The transmittance of the filter 51a is adjustable by changing the thickness of the quartz glass, the number of layers of the quartz glass, the surface rugosity, the impurity density, the impurity particle size, the bubble size, etc. For example, multiple regions having different transmittances may be formed by adjusting the thickness of the quartz glass in multiple regions of the filter 51a.

By using such a filter 51a to perform the first irradiation at the first filter orientation angle θ_{F1} and implement the second irradiation at the second filter orientation angle θ_{F2}, the distribution (e.g., the orientation angle dependency) of the intensity of the light 31 can be changed; the surface temperature history distribution of the wafer 60 can be compensated; and a uniform temperature history in the surface of the wafer 60 can be obtained.

For example, the filter 51a may be used to obtain a difference of the energy density of the light 31 irradiated onto the wafer 60 between the high transmittance region 51H and the low transmittance region 51L of about 1 J/cm². Thereby, the 6σ value of the temperature fluctuation in the surface of the wafer 60 can be reduced from 30° C. in the case where the filter 51a is not used to 10° C., that is, to half or less, in the case where the filter 51a is used.

The multiple regions provided in the filter 51a with mutually different transmittances of the light 31 may be set based on the temperature distribution in the surface of the wafer 60 formed by, for example, one irradiation of the light 31, the number of the multiple irradiations of the light 31, etc.

Although the distribution (e.g., the orientation angle dependency) of the intensity of the light 31 in this specific example is changed by changing the filter orientation angle θ_{F}, the invention is not limited thereto. For example, a filter having multiple regions of different transmittances with respect to the light 31 disposed along the circumference (the circumferential edge direction) may be used, for example, by switching between inserting and not inserting the filter between the light emitting unit 30 and the stage 17 between the first irradiation and the second irradiation.

As illustrated in FIG. 15B, another filter 51b includes a light shielding portion 51S and an opening 510. The surface area of the opening 510 is smaller than that of the major surface of the wafer 60. Multiple irradiations may be performed by disposing such a filter 51b between the light emitting unit 30 and the stage 17 and changing the position of the opening 510 in the circumferential direction. In the case of such multiple irradiations, at least one selected from the energy density and the irradiation duration (the pulse width or the irradiation duration per unit length based on the scan rate in the case described below where a laser is used) of the light 31 may be changed.

In other words, the position of the opening 510 of the filter 51b, where the surface area of the opening 510 is smaller than that of the major surface of the wafer 60, may be moved; the intensity of the light 31 may be adjusted; and the wafer 60 may be multiply irradiated with the light 31.

In other words, by using multiple irradiations and changing at least one selected from the energy density and the duration of the irradiation of the light 31, the temperature unevenness that easily occurs in the case where the major surface of the wafer 60 is collectively irradiated with the light 31 can be improved by limiting the irradiation region to a designated region. Thereby, the adjustment range of the irradiation conditions can be enlarged; and it is easier to improve the temperature fluctuation in the surface of the wafer 60.

Thus, in the heat treatment apparatus 120 according to this embodiment and the method for manufacturing the semiconductor device according to embodiments of the invention, a filter is provided to provide a temperature adjustment function in the circumferential direction of the wafer 60 in which the temperature adjustment function of the heater 18 of the stage 17 is insufficient. By using such a filter, an ultra rapid heat treatment can be implemented with reduced temperature fluctuation in the surface by changing the distribution (e.g., the orientation angle dependency) of the intensity of the light 31.

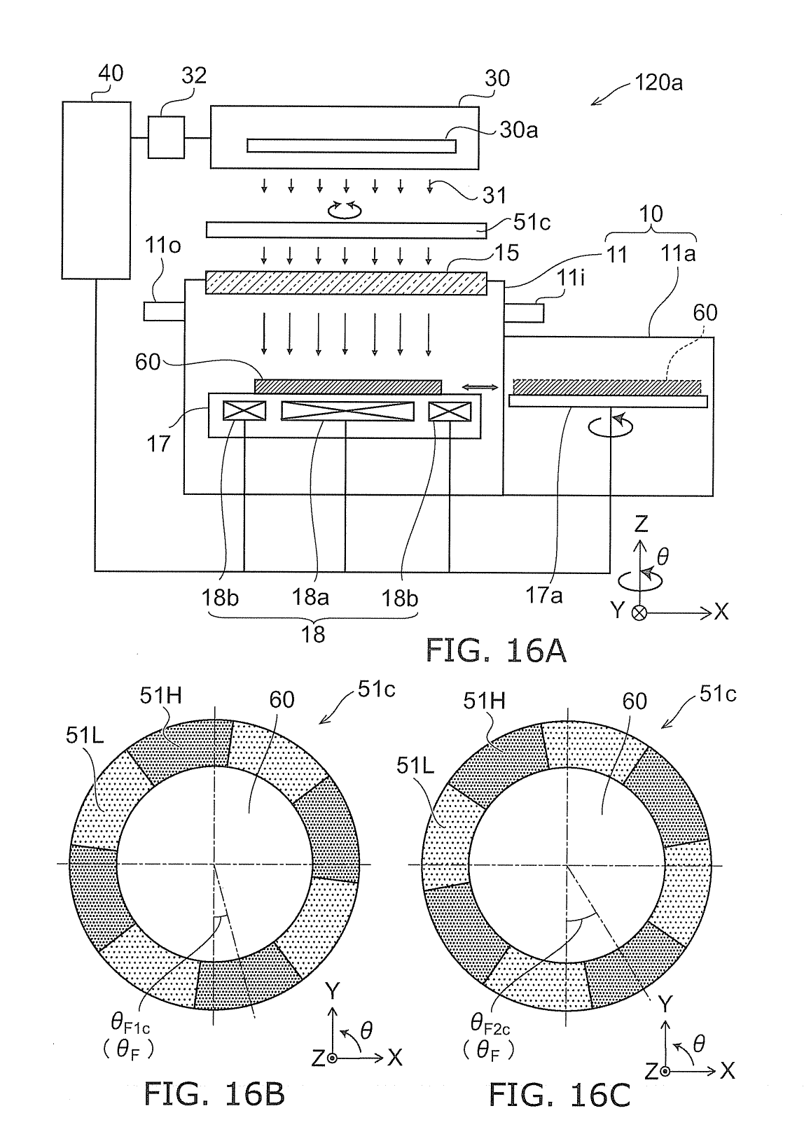

FIGS. 16A to 16C are schematic views illustrating the configuration and operations of another heat treatment apparatus according to the second embodiment.

Namely, FIG. 16A illustrates the configuration of a heat treatment apparatus 120a. FIGS. 16B and 16C illustrate operations during the first processing and the second processing.

In the heat treatment apparatus 120a according to the second embodiment of the invention, a filter 51c is provided between the stage 17 and the light emitting unit 30 to attenuate the light 31 as illustrated in FIG. 16A.

As illustrated in FIGS. 16B and 16C, the filter 51c includes regions having mutually different transmittances of the light 31 in regions outside of the region where the wafer 60 is placed. For example, the filter 51c includes the high transmittance region 51H and the low transmittance region 51L along the circumferential direction of the wafer 60 (the circumferential edge direction of the wafer 60). In such a case as well, the filter 51c includes multiple regions (the high transmittance region 51H and the low transmittance region 51L) having mutually different transmittances of the light 31 disposed along a circumference centered on the center of the major surface of the filter 51c. The multiple regions are disposed to oppose regions outside of the region of the major surface of the stage 17 where the wafer 60 is placed.

In such a case as well, the filter 51c may include, for example, quartz glass; and the transmittance of the filter 51c is adjustable by changing the thickness of the quartz glass, the number of layers of the quartz glass, the surface rugosity, the impurity density, the impurity particle size, the bubble size, etc. For example, in addition to being disposed along the circumferential direction, the multiple regions (the high transmittance region 51H and the low transmittance region 51L) of the filter 51c may be disposed along a direction other than the circumferential direction (e.g., a direction from the center toward the outside).

By using such a filter 51c, the distribution of the intensity of the light 31 on the major surface of the stage 17 is changed after the first irradiation, and the second irradiation is performed. In other words, for example, the orientation angle dependency of the intensity of the light 31 having an axis in a direction perpendicular to the major surface of the stage 17 is changed, and the second irradiation is performed.

For example, during the first irradiation, the orientation angle (a filter orientation angle θ_{Fc}) of the filter 51c is set to a first filter orientation angle θ_{F1c} as illustrated in FIG. 16B. By performing the first irradiation in this state, a surface temperature distribution of the wafer 60 such as, for example, that described in regard to FIG. 3B, that is, a surface temperature distribution having large fluctuation, can be obtained.

In such a case, as illustrated in FIG. 16C, the filter orientation angle θ_{Fc} is changed and set to the second filter orientation angle θ_{F2c} after the first irradiation. By implementing the second irradiation in this state, as a result, the surface temperature history distribution of the wafer 60 is compensated; and a uniform temperature history in the surface of the wafer 60 can be obtained.

In other words, by changing the distribution (e.g., the orientation angle dependency) of the intensity of the light 31 between the first irradiation and the second irradiation, an ultra rapid heat treatment having reduced temperature fluctuation in the surface can be implemented.

Although the case is illustrated in FIGS. 16A to 16C where the configuration of the major surface of the filter 51c is circular, the configuration of the filter 51c is arbitrary.

Thus, by disposing the multiple regions (the high transmittance region 51H and the low transmittance region 51L) having mutually different transmittances outside of the region occupied by the wafer 60, the control of the light 31 is easier than in the case (e.g., the filters 51a and 51b described above) where the multiple regions are disposed inside the region occupied by the wafer 60; and the amount of light irradiated onto the wafer 60 can be finely adjusted. Thereby, it is possible to precisely control an effective annealing temperature.

Two or more of the filters 51a, 51b, and 51c recited above may be provided simultaneously. Also, one filter may include the multiple regions (the high transmittance region 51H and the low transmittance region 51L) having mutually different transmittances of the light 31 on both the inside and the outside of the region occupied by the wafer 60.

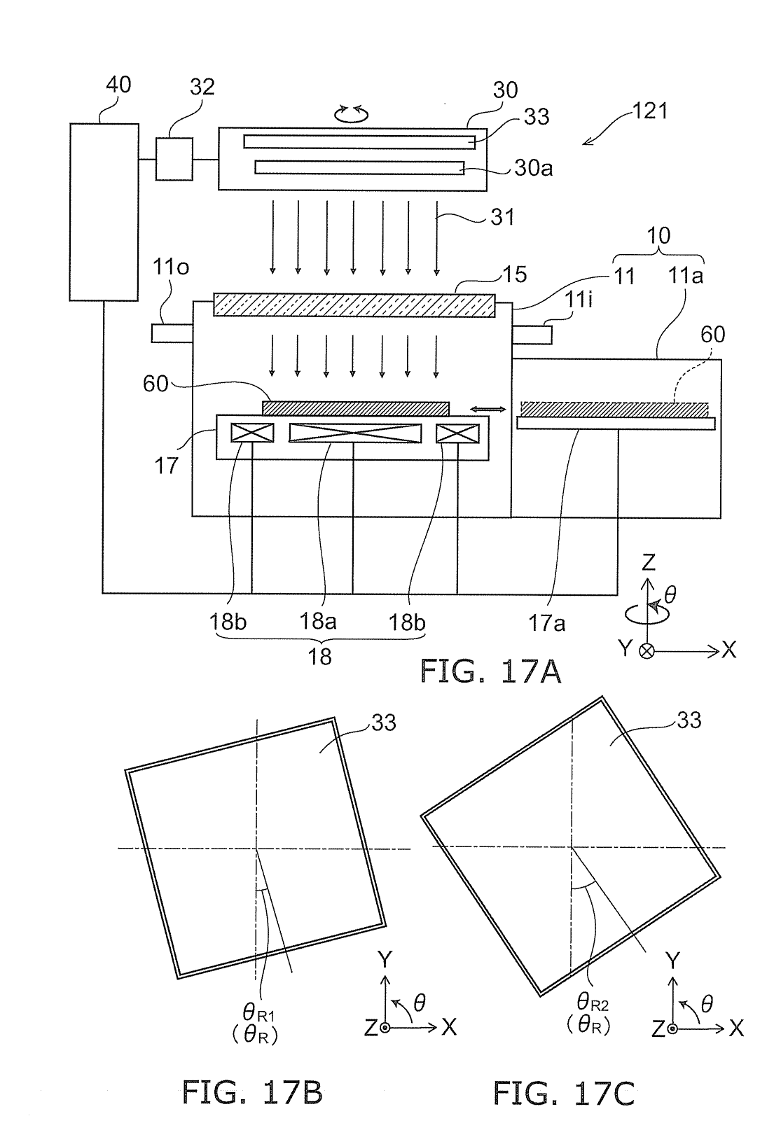

FIGS. 17A to 17C are schematic views illustrating the configuration and operations of another heat treatment apparatus according to the second embodiment.

Namely, FIG. 17A illustrates the configuration of a heat treatment apparatus 121. FIGS. 17B and 17C illustrate operations during the first processing and the second processing, respectively.

In another heat treatment apparatus 121 according to the second embodiment of the invention, the light emitting unit 30 includes a reflecting unit 33 as illustrated in FIG. 17A. The reflecting unit 33 is provided, for example, on the back face side (the side opposite to the processing unit 10) of the lamp 30a.

Using the reflecting unit 33, the distribution of the intensity of the light 31 on the major surface of the stage 17 is changed after the first irradiation, and the second irradiation is performed. In other words, for example, the orientation angle dependency having an axis in a direction perpendicular to the major surface of the stage 17 is changed, and the second irradiation is performed. At this time, the axis may be a direction perpendicular to the major surface of the stage 17 that passes through the center of the major surface of the stage 17.

For example, during the first irradiation, the orientation angle (a reflecting unit orientation angle θ_{R}) of the reflecting unit 33 is set to a first reflecting unit orientation angle θ_{R1} as illustrated in FIG. 17B. By performing the first irradiation in this state, a surface temperature distribution of the wafer 60 such as, for example, that described in regard to FIG. 3B, that is, a surface temperature distribution having large fluctuation, can be obtained.

In such a case, after the first irradiation, the reflecting unit orientation angle θ_{R} is changed and set to a second reflecting unit orientation angle θ_{R2} as illustrated in FIG. 17C. By implementing the second irradiation in this state, as a result, the surface temperature history distribution of the wafer 60 is compensated; and a uniform temperature history in the surface of the wafer 60 can be obtained.

In other words, in such a case as well, by changing the distribution (e.g., the orientation angle dependency) of the intensity of the light 31 between the first irradiation and the second irradiation, an ultra rapid heat treatment having reduced temperature fluctuation in the surface can be implemented.

Although the reflecting unit orientation angle θ_{R} is changed in this specific example to change the distribution (e.g., the orientation angle dependency) of the intensity of the light 31, the invention is not limited thereto. For example, the reflecting unit 33 having multiple regions of different transmittances with respect to the light 31 may be used, for example, by switching between disposing and not disposing the reflecting unit 33 on the back face side, for example, of the light emitting unit 30 between the first irradiation and the second irradiation.

Although the case is illustrated in FIGS. 17A to 17C where the configuration of the major surface of the reflecting unit 33 is rectangular, the configuration of the reflecting unit 33 is arbitrary.

Although the case is described above where the reflecting unit 33 is provided on the side of the lamp 30a opposite to the processing unit 10, the disposition of the reflecting unit 33 is arbitrary. For example, the reflecting unit 33 may be provided at any location in the space between the light emitting unit 30 and the stage 17. For example, the reflecting unit 33 may be disposed to surround an axis in the Z axis direction in a space between the light emitting unit 30 and the stage 17. Also, the reflecting unit 33 may be provided, for example, obliquely above the stage 17 in the interior of the processing unit 10.

The change of the distribution (e.g., the orientation angle dependency) of the intensity of the light 31 by, for example, at least one selected from the filters 51, 51a, 51b, and 51c and the reflecting unit 33 recited above may be implemented by the control unit 40.

As in the heat treatment apparatuses 120, 120a, and 121, the heat treatment apparatus according to this embodiment may further include at least one selected from a filter having multiple regions of mutually different transmittances and a reflecting unit having multiple regions of mutually different reflectances. The dispositions of these filters and reflecting units may be changeable.

The changing of the orientation angle dependency of the intensity of the light 31 includes changing at least one selected from the disposition of the filter provided between the stage 17 and the light emitting unit 30 and the reflective characteristics of the reflecting unit 33 reflecting the light 31 toward the stage 17. The disposition of the filter recited above includes an orientation angle (the filter orientation angle θ_{F}) having an axis in a direction perpendicular to the major surface of the filter. The changing of the reflective characteristics recited above includes changing the orientation angle (the reflecting unit orientation angle θ_{R}) of the reflecting unit 33.

In such a case, the filter recited above may include multiple regions having mutually different transmittances of the light 31 disposed in at least one selected from the inside and the outside of the region of the major surface of the stage 17 where the wafer 60 is placed. The reflecting unit 33 recited above may be provided to oppose a region of the major surface of the stage 17 outside of the region where the wafer 60 is placed.

Although the description recited above is an example in which the light 31 is multiply irradiated and the distribution (e.g., the orientation angle dependency) of the intensity of the light 31 is changed using at least one selected from the filters 51, 51a, 51b, and 51c and the reflecting unit 33, the heating temperature of the wafer 60 may be provided uniformly by one irradiation of the light 31 using at least one selected from the filters 51, 51a, 51b, and 51c and the reflecting unit 33. In other words, the temperature distribution occurring in the wafer 60 by one irradiation of the light 31 can be made uniformly by controlling the distribution of the transmittance of the filters 51, 51a, 51b, and 51c or the reflectance of the reflecting unit 33 to compensate the temperature distribution occurring in the wafer 60 during the one irradiation of the light 31. In such a case, one irradiation with the light 31 is sufficient.

### Third Embodiment

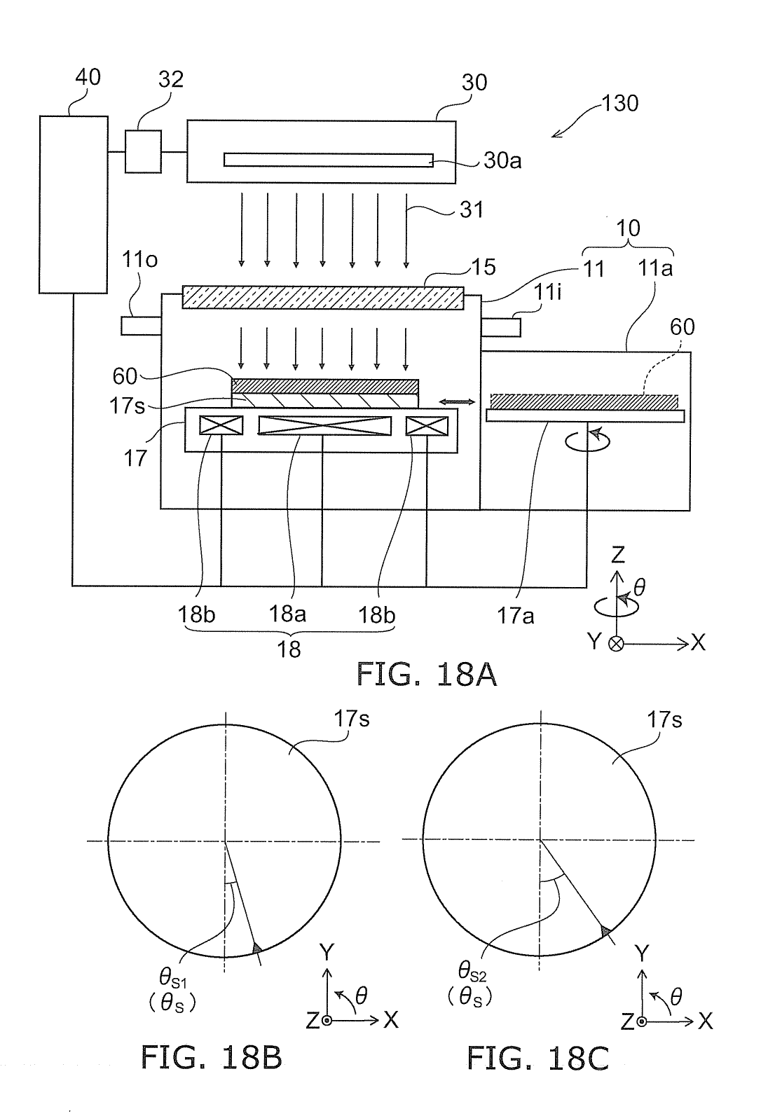

FIGS. 18A to 18C are schematic views illustrating the configuration and operations of a heat treatment apparatus according to a third embodiment. Namely, FIG. 18A illustrates the configuration of a heat treatment apparatus 130. FIGS. 18B and 18C illustrate operations during the first processing and the second processing, respectively.

In the heat treatment apparatus 130 according to the third embodiment of the invention, a susceptor 17s is provided on the major surface of the stage 17, and the wafer 60 is placed on the major surface of the susceptor 17s as illustrated in FIG. 18A.

The distribution of the supplemental heating temperature of the wafer 60 is changed by the stage 17 using the susceptor 17s after the first irradiation, and the second irradiation is performed. In other words, for example, the orientation angle dependency of the supplemental heating temperature having an axis in a direction perpendicular to the major surface of the stage 17 is changed, and the second irradiation is performed. At this time, the axis may be a direction perpendicular to the major surface of the stage 17 that passes through the center of the major surface of the stage 17.

In other words, the temperature of the wafer 60 may have a distribution in the major surface of the wafer 60 due to characteristics of the susceptor 17s such as, for example, thermal conductivity. For example, the distribution of micro gaps between the wafer 60 and the susceptor 17s may be changed along the circumferential direction on the major surface of the susceptor 17s. Thereby, the supplemental heating temperature of the wafer 60 fluctuates along the circumferential direction of the wafer 60 based on the orientation angle (a susceptor orientation angle θ_{S}) of the susceptor 17s.

For example, during the first irradiation, the susceptor orientation angle θ_{S} is set to a first susceptor orientation angle θ_{S1} as illustrated in FIG. 18B. By performing the first irradiation in this state, a surface temperature distribution of the wafer 60 such as, for example, that described in regard to FIG. 3B, that is, a surface temperature distribution having large fluctuation, can be obtained.

In such a case, as illustrated in FIG. 18C, the susceptor orientation angle θ_{S} is changed and set to the second susceptor orientation angle θ_{S2} after the first irradiation. By implementing the second irradiation in this state, as a result, the surface temperature history distribution of the wafer 60 is compensated; and a uniform temperature history in the surface of the wafer 60 can be obtained.

In other words, by changing the distribution (e.g., the orientation angle dependency) of the supplemental heating temperature of the wafer 60 along the circumferential edge direction of the wafer 60 between the first irradiation and the second irradiation, an ultra rapid heat treatment having reduced temperature fluctuation in the surface can be implemented.

Also, the thermal characteristics of the major surface of the susceptor 17s may be controlled to the desired state.

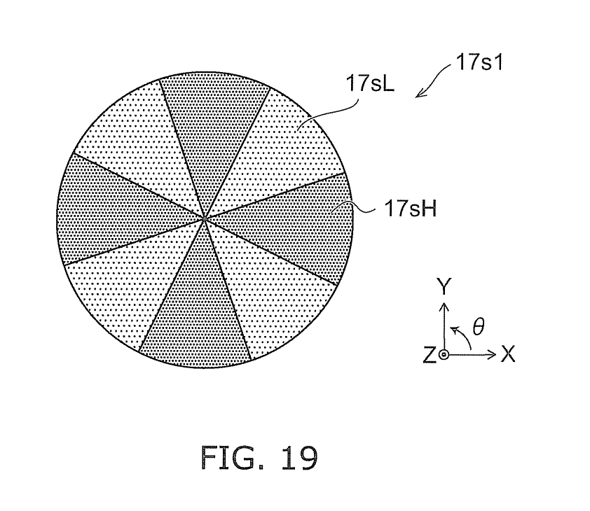

FIG. 19 is a schematic view illustrating a susceptor used in the heat treatment apparatus according to the third embodiment.

As illustrated in FIG. 19, a susceptor 17s1 used in the heat treatment apparatus 130 according to this embodiment includes a high thermal conductivity region 17sH and a low thermal conductivity region 17sL.

In other words, the susceptor 17s1 includes multiple regions (the high thermal conductivity region 17sH and the low thermal conductivity region 17sL) having mutually different thermal conductivities disposed along a circumference centered on the center of the major surface of the susceptor 17s1.

In this specific example, four of each of the high thermal conductivity region 17sH and the low thermal conductivity region 17sL are disposed such that the orientation angles θ are 90 degrees apart and the difference from the orientation angle θ of the high thermal conductivity region 17sH to the orientation angles θ of the adjacent low thermal conductivity regions 17sL is 45 degrees.

The high thermal conductivity region 17sH and the low thermal conductivity region 17sL having mutually different thermal conductivities may be provided, for example, by disposing a supplemental susceptor made of SiC, AIN, etc., which has a thermal conductivity higher than that of quartz, to form the high thermal conductivity region 17sH in a susceptor main body made of a quartz plate.

The distribution (e.g., the orientation angle dependency) of the supplemental heating temperature of the wafer 60 can be changed by using such a susceptor 17s1, performing the first irradiation at the first susceptor orientation angle θ_{S1}, and implementing the second irradiation at the second susceptor orientation angle θₛ₂; the surface temperature history distribution of the wafer 60 can be compensated; and a uniform temperature history in the surface of the wafer 60 can be obtained.

The multiple regions having mutually different thermal conductivities provided in the susceptor 17s1 may be set based on, for example, the temperature distribution in the surface of the wafer 60 formed by one irradiation with the light 31 and the number of multiple irradiations with the light 31.

As in the heat treatment apparatus 130, the heat treatment apparatus according to this embodiment may further include a susceptor having multiple regions of mutually different thermal conductivities. The disposition of such a susceptor may be changeable.

The temperature of the wafer 60 is determined based on both the supplemental heating by the stage 17 via the susceptor and the heating with the light 31. Accordingly, the configuration of the susceptor and the material of the susceptor may be changed in portions to compensate the surface temperature distribution of the wafer 60 of one irradiation with the light 31. Thereby, the fluctuation in the surface of the temperature of the wafer 60 for one irradiation with the light 31 can be suppressed. In such a case, the heat treatment of the wafer 60 can be completed with only one irradiation.

For example, the temperature of the supplemental heating of the wafer 60 is controlled by making the thermal conductivity of the susceptor relatively high in regions where the temperature of the wafer 60 due to one irradiation with the light 31 is low. Thereby, the temperature of the wafer 60 increasing based on both the supplemental heating and the irradiation with the light 31 can be made uniform.

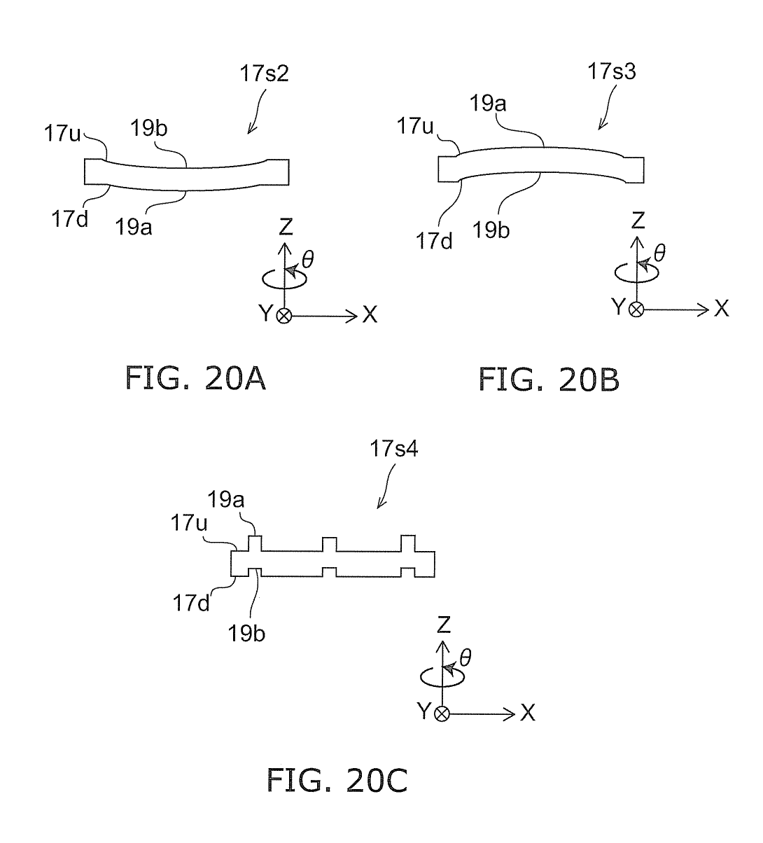

FIGS. 20A to 20C are schematic cross-sectional views illustrating other susceptors used in the heat treatment apparatus according to the third embodiment.

Namely, FIGS. 20A to 20C are schematic cross-sectional views when the susceptors are cut in a plane including a direction perpendicular to the major surface of the susceptor.

In other susceptors 17s2 to 17s4 used in the heat treatment apparatus according to this embodiment, a recess 19b and a protrusion 19a are provided in mutually corresponding positions on an upper face 17u and a lower face 17d as illustrated in FIGS. 20A to 20C.

Here, the face of the susceptors 17s2 to 17s4 opposing the stage 17 is taken as the lower face 17d. The face on the side of the susceptors 17s2 to 17s4 opposite to the stage 17 on which the wafer 60 is placed is taken as the upper face 17u.

In other words, in the susceptor 17s2 illustrated in FIG. 20A, the recess 19b is provided in the central portion of the upper face 17u; and the protrusion 19a is provided in the central portion of the lower face 17d.

In the susceptor 17s3 illustrated in FIG. 20B, the protrusion 19a is provided in the central portion of the upper face 17u; and the recess 19b is provided in the central portion of the lower face 17d.

In the susceptor 17s4 illustrated in FIG. 20C, the protrusion 19a is provided in the central portion and the peripheral portion of the upper face 17u; and the recess 19b is provided in the central portion and the peripheral portion of the lower face 17d.

Thus, in the plane substantially parallel to the major surface of the susceptors 17s2 to 17s4, the protrusion 19a is provided on the lower face 17d at a position corresponding to the recess 19b provided on the upper face 17u; or the recess 19b is provided on the lower face 17d at a position corresponding to the protrusion 19a provided on the upper face 17u. Thereby, the recess 19b and the protrusion 19a can be provided on either the upper face 17u or the lower face 17d while the thickness of the susceptors 17s2 to 17s4 is substantially constant in substantially all portions. In other words, the upper face 17u and the lower face 17d of the susceptors 17s2 to 17s4 have opposite configurations.

By using such susceptors 17s2 to 17s4 to change the susceptor orientation angle θ_{S} of the susceptors 17s2 to 17s4 between the first irradiation and the second irradiation, an ultra rapid heat treatment having reduced temperature fluctuation in the surface can be implemented.

In other words, the changing of the orientation angle dependency of the supplemental heating temperature includes changing the disposition of the susceptor provided on the major surface of the stage 17 on which the wafer 60 is placed. The changing of the disposition of the susceptor includes changing the orientation angle having an axis in a direction perpendicular to the major surface of the susceptor.

The high thermal conductivity region 17sH and the low thermal conductivity region 17sL having mutually different thermal conductivities of the susceptors recited above may be disposed to oppose at least one selected from the inside and the outside of the region of the major surface of the stage 17 where the wafer 60 is placed.

Although the description recited above is an example in which the distribution (e.g., the orientation angle dependency) of the supplemental heating temperature of the wafer 60 is changed by the stage 17 after the first irradiation using the susceptors 17s and 17s1 to 17s4, in the case where, for example, the heater 18 has a configuration in which multiple portions thereof are separated in the circumferential direction to have independently controllable temperatures, the temperature distribution of the wafer 60 may be suppressed by changing the distribution (e.g., the orientation angle dependency) of the supplemental heating temperature by changing the temperature distribution of the heater 18 between the first irradiation and the second irradiation.

The susceptors 17s2 to 17s4 also can reduce the surface temperature distribution of the wafer 60 in one irradiation with the light 31.

It is not always necessary for the upper face 17u of the susceptor to be planar. For example, the upper face 17u of the susceptor may have recesses and protrusions to suppress cracks of the wafer 60 when placing the wafer 60 on the susceptor, suppress thermal stress, and suppress dust from adhering onto the back face of the wafer 60. For example, a protrusion, embossing, or recess may be provided on the upper face 17u of the susceptor. Thus, in the case where recesses and protrusions exist on the upper face 17u of the susceptor, the contact surface area between the wafer 60 and the susceptor is reduced, which may cause temperature unevenness during the supplemental heating of the wafer 60 by the stage 17.

In the case where the temperature distribution of the wafer 60 in one irradiation with the light 31 is caused by temperature unevenness of the supplemental heating of the wafer 60 by the stage 17, the temperature distribution of the wafer 60 of one irradiation with the light 31 can be suppressed by reducing the temperature unevenness of the supplemental heating.

In other words, as in the susceptors 17s2 to 17s4, the protrusion 19a is provided on the lower face 17d at a position corresponding to the recess 19b provided on the upper face 17u and the recess 19b is provided on the lower face 17d at a position corresponding to the protrusion 19a provided on the upper face 17u. Thereby, the lower face 17d of the susceptor contacts the upper face of the stage 17 in a region where the upper face 17u does not contact the wafer 60. Thereby, the distribution in the surface of the temperature of the supplemental heating of the wafer 60 can be averaged.

The first to third embodiments recited above may be implemented in combination. The heat treatment apparatus according to the embodiments of the invention may further include two or more of at least one selected from the wafer disposition control unit 20, the detection unit 16, the filters 51, 51a, 51b, and 51c, the reflecting unit 33, and the susceptors 17s and 17s1 to 17s4 recited above.

### Fourth Embodiment

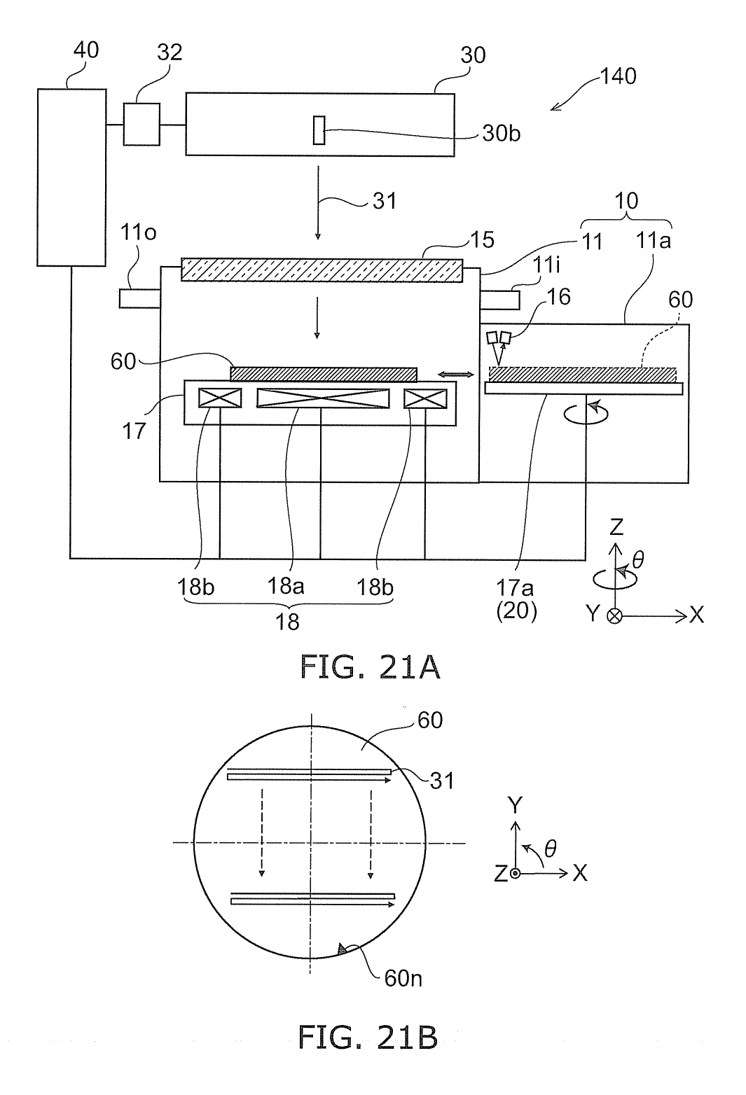

FIGS. 21A and 21B are schematic views illustrating the configuration and operations of a heat treatment apparatus according to a fourth embodiment. Namely, FIG. 21A illustrates the configuration of a heat treatment apparatus 140. FIG. 21B illustrates the irradiation state of the light 31.

As illustrated in FIG. 21A, the light emitting unit 30 includes a laser 30b in the heat treatment apparatus 140 according to the fourth embodiment of the invention.

As illustrated in FIG. 21B, the light 31 emitted by the laser 30b is scanned. In other words, the light 31 is a laser light scanned over the major surface of the wafer 60.

In such a case as well, the durations of the first irradiation and the second irradiation are shorter than the time necessary for the changing of step S120.

For example, in the case where the laser 30b is a pulse laser, the pulse width of the light 31 emitted by the laser 30b is shorter than the time necessary for the changing of step S120.

In other words, in the case of a pulse laser, the laser 30b emits laser light (the light 31) having a pulse width not less than 0.1 ms and not more than 100 ms. Each of the surface portions of the wafer 60 irradiated with each amount of the light 31 (the laser pulse) emitted by the laser 30b is substantially irradiated as with the light 31 having a pulse width not less than 0.1 ms and not more than 100 ms. In such a case, a substantially similar operation is implemented as in the case where, for example, the lamp 30a such as a xenon flash lamp is used as described in regard to the first to third embodiments; and similar effects are obtained.

Further, the laser 30b may include a continuous emission laser. In such a case, the scanning is performed such that the time for the light 31 emitted by the laser 30b to pass over the distance corresponding to the size of each of the multiple semiconductor devices provided in the wafer 60 is shorter than the time necessary for the changing of step S120. In other words, the time for the scanned light 31 to pass over the distance corresponding to the size of each of the multiple semiconductor devices provided in the wafer 60 is not less than 0.1 milliseconds and not more than 100 milliseconds. In such a case, the semiconductor device may be taken to be a semiconductor chip multiply provided in the wafer 60 or each of the multiple elements provided in each of the semiconductor chips.

Thus, also in the case where the continuous emission laser 30b is used, each location of the major surface of the wafer 60 irradiated with the laser light (the light 31) undergoes a heat treatment substantially equivalent to that in which a light pulse having a pulse width not less than 0.1 milliseconds and not more than 100 milliseconds is irradiated. Accordingly, in such a case as well, a substantially similar operation is implemented as in the case where, for example, the lamp 30a such as a xenon flash lamp is used as described in regard to the first to third embodiments; and similar effects are obtained.

As described above, it is desirable for the wavelength of the light 31 of the laser 30b to be 500 nm to 11 μm. The laser 30b may include various lasers such as an excimer laser, YAG laser, carbon monoxide gas laser, and carbon dioxide laser.

Also in the heat treatment apparatus 140 using such laser light, the control unit 40 may perform similar operations as those described in regard to the heat treatment apparatuses 110 to 113 according to the first embodiment.

Also in the heat treatment apparatus 140 using the laser light, the control unit 40 may perform similar operations as those described in regard to the heat treatment apparatuses 120, 120a, and 121 according to the second embodiment and the heat treatment apparatus 130 according to the third embodiment.

Thus, according to the heat treatment apparatus 140, an ultra rapid heat treatment having reduced temperature fluctuation in the surface can be implemented. Thereby, a shallow active layer having a low resistance can be formed with good uniformity; and a high performance semiconductor device can be manufactured with high productivity.

The processing described in regard to FIGS. 8A to 8E and FIGS. 9A to 9G can be implemented using the heat treatment apparatuses 111 to 113, 120, 120a, 121, 130, and 140 recited above. Thereby, a semiconductor device can be manufactured.

Although the case is described in which the heat treatment apparatuses 110 to 113, 120, 120a, 121, 130, and 140 recited above include one processing unit 10, multiple processing units 10 may be provided in one heat treatment apparatus. Thereby, heat treatment can be implemented with higher productivity. In the case where multiple processing units 10 are provided, the light emitting unit 30 may be multiply provided to correspond to each of the processing units 10. Thus, also in the case where multiple processing units 10 and multiple light emitting units 30 are provided, it is sufficient to use one control unit 40.

### Fifth Embodiment

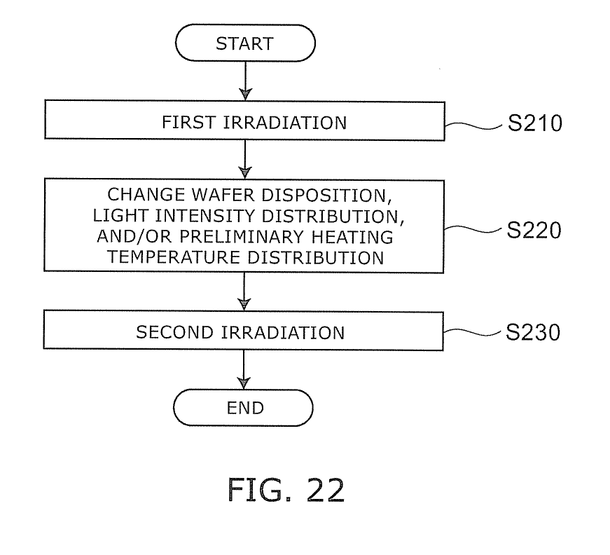

FIG. 22 is a flowchart illustrating a method for manufacturing a semiconductor device according to a fifth embodiment.

As illustrated in FIG. 22, first, the first irradiation is implemented to irradiate the wafer 60 with the light 31 (step S210).

An impurity, for example, is implanted into the wafer 60.

Then, after the first irradiation, at least one selected from the disposition (e.g., the wafer orientation angle θ_{W}, i.e., an orientation angle of the wafer 60 having an axis in a direction perpendicular to the major surface of the wafer 60) of the wafer, the distribution (e.g., the orientation angle dependency having an axis in a direction perpendicular to the major surface of the wafer 60) of the intensity of the light 31 on the major surface of the wafer 60, and the distribution (e.g., the orientation angle dependency having an axis in a direction perpendicular to the major surface of the wafer 60) of the supplemental heating temperature of the wafer 60 is changed from that of the first irradiation (step S220).

Then, in the state after the changing, the second irradiation is implemented to irradiate the wafer 60 with the light 31 (step S230).

The durations of the first irradiation and the second irradiation recited above are shorter than the time necessary for the change implemented in step S120.

In other words, the light 31 is irradiated for not less than 0.1 milliseconds and not more than 100 milliseconds.

In other words, the processing described, for example, in regard to FIGS. 8A to 8E and FIGS. 9A to 9G is implemented.

Although an activation heat treatment of the impurity ion implanted into the wafer 60 is described above, the invention is not limited thereto. In other words, the heat treatment apparatus and the semiconductor device manufacturing method according to the various embodiments recited above may be applied to various heat treatments such as, for example, heat treatment during insulating film formation of various oxide films, various nitride films, etc., and heat treatment to monocrystallinize or increase the particle size of amorphous silicon or polysilicon to provide similar effects.

Although the case is described above where the orientation angle is an orientation angle around an axis centered on at least one selected from the center of the major surface of the wafer 60 and the center of the major surface of the stage 17, the center forming the reference of the orientation angle is arbitrary. In other words, the center of the orientation of the wafer orientation angle θ_{W}, the orientation angle dependency of the intensity of the light 31, and the orientation angle dependency of the supplemental heating temperature may be, for example, somewhere other than the center of the major surface of the wafer 60 and the center of the major surface of the stage 17. Accordingly, the disposition of the wafer 60 may be moved to any position in the X-Y plane. The orientation angle dependency of the intensity of the light 31 may be a dependency of the intensity of the light 31 along any direction in the X-Y plane; and it is sufficient for this dependency to be changed. Similarly, the orientation angle dependency of the supplemental heating temperature may be a dependency of the temperature due to the supplemental heating of the wafer 60 along any direction in the X-Y plane; and it is sufficient for this dependency to be changed.

Thus, in the heat treatment apparatus and the methods for manufacturing the semiconductor device according to the embodiments of the invention, a function is added to adjust the temperature along a direction for which direct temperature control by a heat source such as the light emitting unit 30 and the heater 18 is difficult.

Hereinabove, exemplary embodiments of the invention are described with reference to specific examples. However, the invention is not limited to these specific examples. For example, one skilled in the art may appropriately select specific configurations of components of heat treatment apparatuses such as light emitting units, lamps, lasers, power sources, reflecting units, filters, processing units, processing chambers, antechambers, stage sections, susceptors, heaters, control units, and the like from known art and similarly practice the invention. Such practice is included in the scope of the invention to the extent that similar effects thereto are obtained.

Further, any two or more components of the specific examples may be combined within the extent of technical feasibility; and are included in the scope of the invention to the extent that the purport of the invention is included.

Moreover, all heat treatment apparatuses and methods for manufacturing semiconductor devices practicable by an appropriate design modification by one skilled in the art based on the heat treatment apparatuses and the methods for manufacturing semiconductor devices described above as exemplary embodiments of the invention also are within the scope of the invention to the extent that the purport of the invention is included.

Furthermore, various modifications and alterations within the spirit of the invention will be readily apparent to those skilled in the art. All such modifications and alterations should therefore be seen as within the scope of the invention. For example, additions, deletions, or design modifications of components or additions, omissions, or condition modifications of processes appropriately made by one skilled in the art in regard to the embodiments described above are within the scope of the invention to the extent that the purport of the invention is included.

While certain embodiments have been described, these embodiments have been presented by way of example only, and are not intended to limit the scope of the inventions. Indeed, the novel apparatus and methods described herein may be embodied in a variety of other forms; furthermore, various omissions, substitutions and changes in the form of the apparatus and methods described herein may be made without departing from the spirit of the inventions. The accompanying claims and their equivalents are intended to cover such forms or modifications as would fall within the scope and spirit of the invention.

1. A heat treatment apparatus, comprising:
a light emitting unit configured to emit light to irradiate a wafer;
a processing unit including a stage section, the wafer being placed on the stage section; and
a control unit,
the control unit
implementing a first irradiation to irradiate the light onto the wafer placed on the stage section,
changing, after the first irradiation, at least one selected from a disposition of the wafer, a distribution of an intensity of the light on a major surface of the stage section along a circumferential edge direction of the wafer, and a distribution of a temperature of the wafer in a supplemental heating by the stage section along a circumferential edge direction of the wafer, and
implementing, after the changing, a second irradiation to irradiate the light onto the wafer,
a duration of the first irradiation and a duration of the second irradiation being shorter than a time necessary for the changing.

2. The apparatus according to claim 1, wherein the disposition of the wafer is a relative orientation angle of the wafer with respect to the processing unit.

3. The apparatus according to claim 1, wherein
the processing unit further includes a processing chamber and an antechamber, the stage section being disposed in the processing chamber, the antechamber being jointly provided with the processing chamber, and
the disposition of the wafer is changed in at least one selected from the processing chamber and the antechamber.

4. The apparatus according to claim 3, wherein
the processing unit further includes:
a processing chamber, the stage section being disposed in the processing chamber; and
a wafer disposition control unit provided in the processing chamber to change a disposition of the wafer.

5. The apparatus according to claim 4, wherein
the stage section includes:
an inner heater to oppose a central portion of the wafer; and
an outer heater provided around the inner heater, and
the wafer disposition control unit is provided in a gap between the inner heater and the outer heater.

6. The apparatus according to claim 5, wherein
the wafer disposition control unit is movable along a direction perpendicular to the major surface of the stage section, and
the wafer disposition control unit is movable in the gap along a circumference centered on a central portion of the stage section.

7. The apparatus according to claim 1, wherein a plurality of the wafers are placed on the major surface of the stage section, and the changing after the first irradiation includes changing a relative disposition of the plurality of the wafers with respect to the processing unit.

8. The apparatus according to claim 1, wherein
the processing unit further includes a detection unit configured to detect the disposition of the wafer, and
the control unit causes the disposition of the wafer to change based on a detection result of the disposition of the wafer detected by the detection unit.

9. The apparatus according to claim 1, wherein the changing of the distribution of the intensity of the light along the circumferential edge direction of the wafer includes a changing of a disposition of a filter provided between the stage section and the light emitting unit.

10. The apparatus according to claim 9, wherein the filter has a plurality of regions disposed along a circumferential edge direction of the filter, the plurality of regions having different transmittances with respect to the light.

11. The apparatus according to claim 9, wherein at least one selected from a thickness of the filter, a rugosity of the filter, a density of an impurity contained in the filter, a particle size of the impurity contained in the filter, and a size of a bubble contained in the filter is different along the circumferential edge direction of the filter.

12. The apparatus according to claim 1, wherein the changing the distribution of the intensity of the light along the circumferential edge direction of the wafer includes changing a reflective characteristic of a reflecting unit reflecting the light toward the stage section.

13. The apparatus according to claim 1, wherein the stage section includes a susceptor provided on the major surface of the stage section, the wafer being placed on the susceptor, a changing the distribution of the supplemental heating temperature includes changing a disposition of the susceptor along a circumferential edge direction of the susceptor.

14. The apparatus according to claim 1, wherein an irradiation energy of the light of the first irradiation and an irradiation energy of the light of the second irradiation are not less than 10 joules/cm² and not more than 100 joules/cm².

15. The apparatus according to claim 1, wherein the light emitting unit includes at least one selected from a lamp using at least one selected from noble gas, mercury, and hydrogen: a laser at least one selected from an excimer laser, a YAG laser, a carbon monoxide gas laser and a carbon dioxide laser; and a xenon flash lamp.

16. A method for manufacturing a semiconductor device, comprising:
implementing a first irradiation to irradiate light onto a wafer;
changing, after the first irradiation, at least one selected from
a disposition of the wafer,
a distribution of an intensity of the light on a major surface of the wafer along a circumferential edge direction of the wafer, and
a distribution of a supplemental heating temperature of the wafer along the circumferential edge direction of the wafer; and
implementing, after the changing, a second irradiation to irradiate the light onto the wafer,
a duration of the first irradiation and a duration of the second irradiation being shorter than a time necessary for the changing.

17. The method according to claim 16, further comprising:
forming a gate insulating film on a semiconductor layer included in the wafer and forming a gate electrode on the gate insulating film; and
implanting an impurity ion into the semiconductor layer using the gate electrode as a mask,
the first irradiation being performed after the implantation.

18. The method according to claim 17, wherein a duration of the first irradiation and a duration of the second irradiation are not less than 0.1 milliseconds and not more than 100 milliseconds.

19. The method according to claim 16, wherein an irradiation energy of the light of the first irradiation and an irradiation energy of the light of the second irradiation are not less than 10 joules/cm² and not more than 100 joules/cm².

20. The method according to claim 16, wherein an angle of the changing is substantially a multiple of 45 degrees.
